(19) United States
(12) Patent Application Publication
(10) Pub. No.: US 2024/0373636 A1
(43) Pub. Date: Nov. 7, 2024

(54) METHODS OF FORMING MICROELECTRONIC DEVICES INCLUDING STAIRCASE STRUCTURES, AND RELATED MICROELECTRONIC DEVICES

(71) Applicant: Micron Technology, Inc., Boise, ID (US)

(72) Inventors: Matthew J. King, Boise, ID (US); David H. Wells, Boise, ID (US); Yiping Wang, Boise, ID (US); Mojtaba Asadirad, Boise, ID (US); Harsh Narendrakumar Jain, Boise, ID (US)

(21) Appl. No.: 18/621,738

(22) Filed: Mar. 29, 2024

Related U.S. Application Data
(60) Provisional application No. 63/499,306, filed on May 1, 2023.

(51) Int. Cl. H10B 43/27; H10B 41/27

(52) U.S. Cl. CPC H10B 43/27; H10B 41/27

(57) ABSTRACT

A method of forming a microelectronic device comprises forming a preliminary stack structure over a source structure. The preliminary stack structure comprises a vertically alternating sequence of insulative material and sacrificial material arranged in preliminary tiers. The method comprises forming a staircase structure having steps comprising edges of at least some of the preliminary tiers of the preliminary stack structure, forming implant regions within exposed portions of the sacrificial material at the steps of the staircase structure, forming openings extending through the preliminary stack structure to the source structure and within a horizontal area of the staircase structure, replacing portions of the sacrificial material with conductive structures, forming strapping structures comprising conductive material, at locations vacated by the implant regions, laterally adjacent to the conductive structures at the steps of the staircase structure, and forming conductive contacts within the openings. Additional methods and microelectronic devices are also described.

### CROSS-REFERENCE TO RELATED APPLICATION

This application claims the benefit under 35 U.S.C. § 119(e) of U.S. Provisional Patent Application Ser. No. 63/499,306, filed May 1, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices (e.g., memory devices, such as 3D NAND memory devices) including staircase structures, and related microelectronic devices.

### BACKGROUND

A continuing goal of the microelectronics industry has been to increase the memory density (e.g., the number of memory cells per memory die) of memory devices, such as non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in one or more conductive stack structures including tiers of conductive structures and insulative structures. Each vertical memory string may include at least one select device coupled in series to a serial combination of vertically stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Vertical memory array architectures generally include electrical connections between the conductive structures of the tiers of the conductive stack structure(s) of the memory device and access lines (e.g., word lines) so that the memory cells of the vertical memory array can be uniquely selected for writing, reading, or erasing operations. One method of forming such an electrical connection includes forming so-called “staircase” (or “stair step”) structures at edges (e.g., horizontal ends) of the tiers of the conductive stack structure(s) of the memory device. The staircase structure includes individual “steps” defining contact regions of the conductive structures, upon which conductive contact structures can be positioned to provide electrical access to the conductive structures.

As vertical memory array technology has advanced, additional memory density has been provided by forming vertical memory arrays to include stacks comprising additional tiers of conductive structures and, hence, additional staircase structures and/or additional steps in individual staircase structures associated therewith. As the height of the stacks increases to facilitate additional memory cells in the vertical memory arrays, the stacks may be prone to toppling or collapse during various processing acts. For example, during replacement gate processing acts, the stacks may be subject to tier collapse during or after removal of portions of the tiers to be replaced with the conductive structures. Collapse of the portions of the stacks may reduce reliability of the vertical memory strings.

In addition, as the dimensions and spacing of the conductive features decrease, multilevel wiring structures have been used in memory devices to electrically connect the conductive features to one another. The memory device includes the wiring structures at different levels, with the wiring structures formed of electrically conductive materials to provide conductive pathways through the memory device. As the dimensions and spacing of the conductive features continue to decrease, parasitic (e.g., stray) capacitance between adjacent conductive features within the memory device increases. The increased parasitic capacitance causes higher power demands and delay of the memory device.

### BRIEF DESCRIPTION OF THE DRAWINGS

FIGS. 1A through 1I are simplified, partial top-down views (FIGS. 1A, 1E, and 1H) and simplified, partial cross-sectional views (FIGS. 1B through 1D, IF, 1G, and 1I) illustrating different processing stages of a method of forming a microelectronic device, in accordance with embodiments of the disclosure;

FIGS. 2A through 2D are simplified, partial cross-sectional views illustrating a method of forming a microelectronic device, in accordance with additional embodiments of the disclosure;

FIG. 3 is a simplified, partial cutaway perspective view of a microelectronic device, in accordance with embodiments of the disclosure;

FIG. 4 is a schematic block diagram of an electronic system, in accordance with embodiments of the disclosure; and

FIG. 5 is a schematic block diagram of a processor-based system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device, such as NAND Flash memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 108.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material, such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including an insulative material.

As used herein, the term “sacrificial,” when used in reference to a material or structure, means and includes a material, structure, or a portion of a material or structure that is formed during a fabrication process but that is at least partially removed (e.g., substantially removed) prior to completion of the fabrication process.

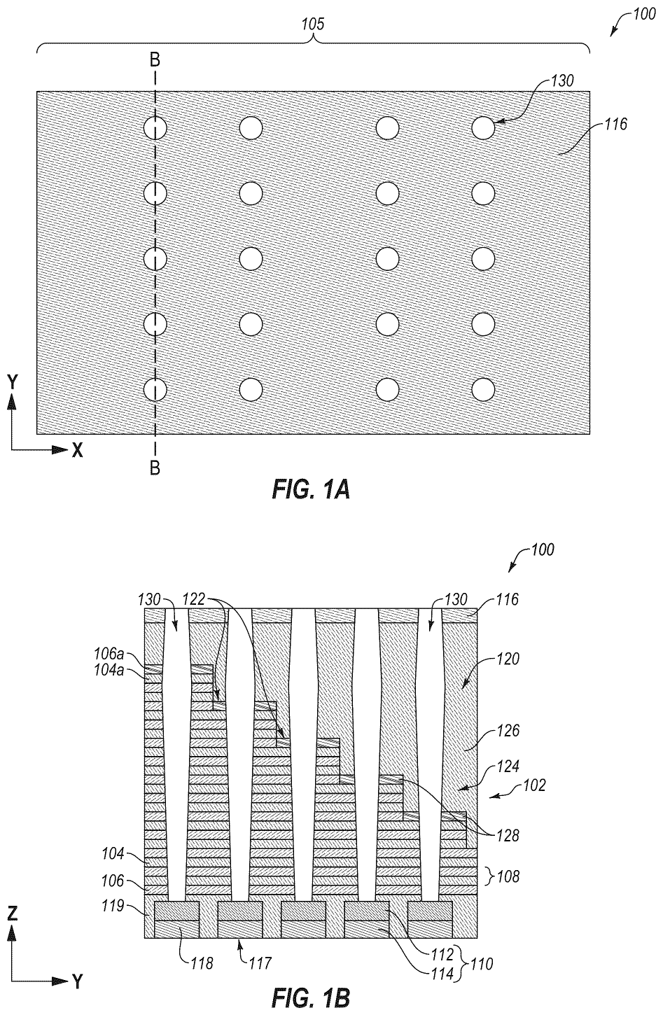

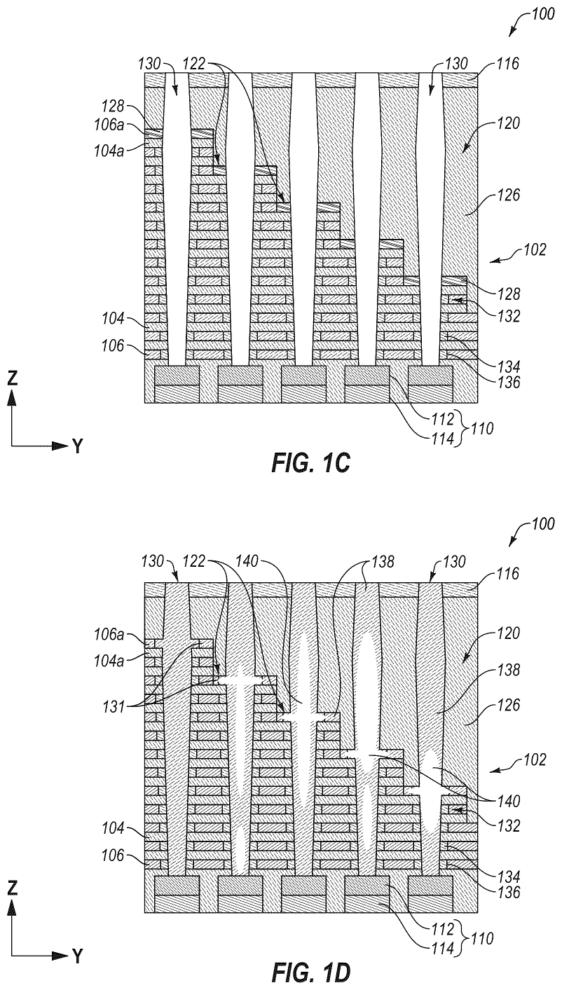

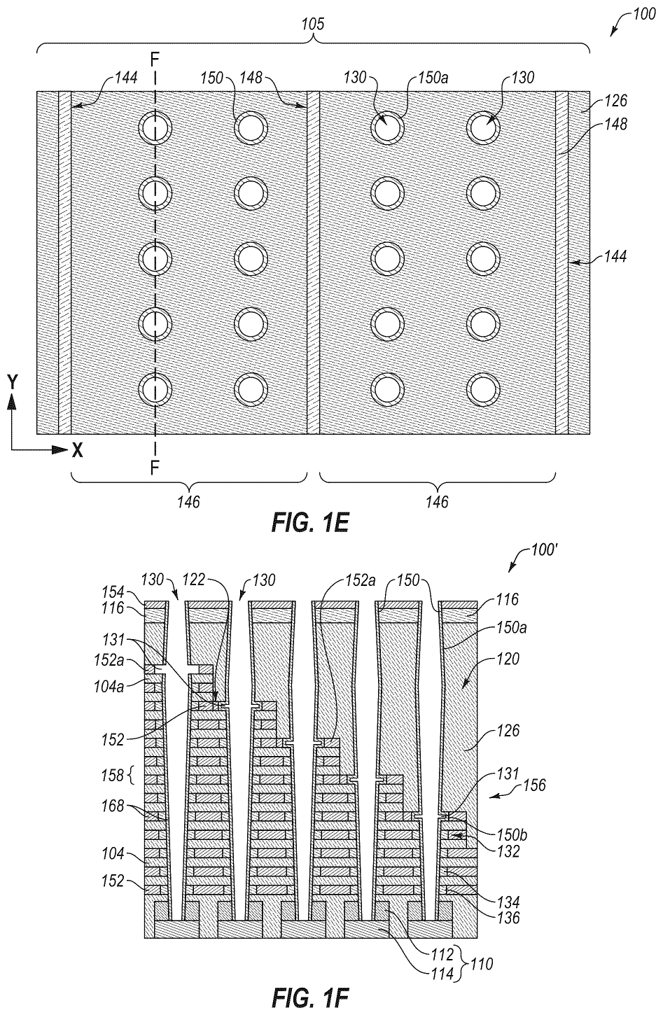

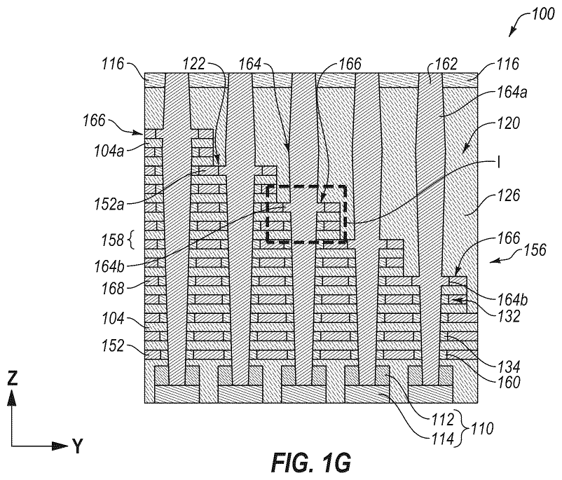

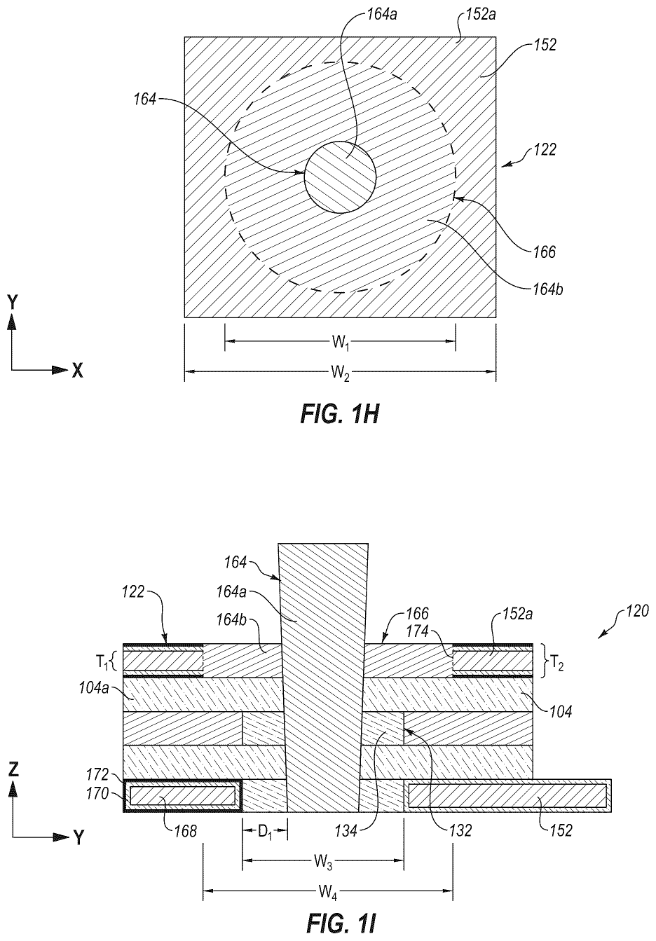

FIGS. 1A through II are simplified, partial top-down views (FIGS. 1A, 1E, and 1H) and simplified, partial cross-sectional views (FIGS. 1B through 1D, 1F, 1G, and 1I) illustrating different processing stages of a method of forming a microelectronic device (e.g., a memory device, such as a three-dimensional (3D) NAND Flash memory device), in accordance with embodiments of the disclosure. FIG. 1H illustrates an enlarged portion of a top-down view of a portion of FIG. 1G, and FIG. 1I illustrates an enlarged portion of the cross-sectional view of box I of FIG. 1G. With the description provided below, it will be readily apparent to one of ordinary skill in the art that the methods and structures described herein with reference to FIGS. 1A through 1I may be used in the formation and configuration of various devices and electronic systems. The methods of the disclosure may be used whenever it is desired to form a microelectronic device.

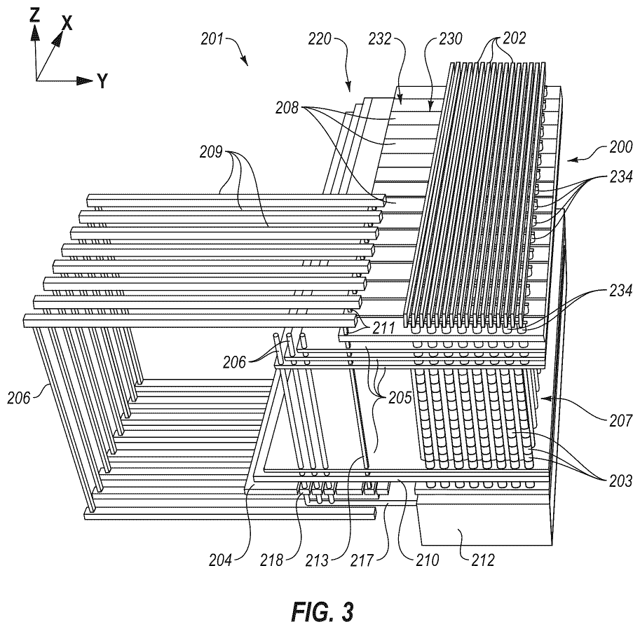

Referring to FIG. 1A, a microelectronic device structure 100 may be formed to include a preliminary stack structure 102 (FIG. 1B). Dielectric material 116 may, optionally, be formed to vertically overlie (e.g., in the Z-direction) the preliminary stack structure 102. The microelectronic device structure 100 may include a staircase region 105 including one or more staircase structures 120 (FIG. 1B). The microelectronic device structure 100 may also include an array region horizontally (e.g., in the X-direction) neighboring the staircase region 105. For example, the array region may include memory pillar structures (e.g., cell pillar structures) employed as memory cells (e.g., strings of NAND memory cells), as described in further detail with reference to FIG. 3. Features of the array region of the microelectronic device structure 100 may be formed during (e.g., substantially simultaneous with) formation of corresponding features of the staircase region 105. Openings 130 may be formed to vertically extend (e.g., in the Z-direction) through one or more materials overlying the staircase structure 120 within the staircase region 105. The preliminary stack structure 102 of the staircase region 105 is described in further detail below, along with additional components (e.g., structures, features) of the microelectronic device structure 100 at the processing stage depicted in FIG. 1A. FIG. 1B is a simplified, partial cross-sectional view of the microelectronic device structure 100 about the line B-B shown in FIG. 1A. For clarity and case of understanding of the drawings and related description, not all features depicted in one of FIGS. 1A and 1B are depicted in the other of FIGS. 1A and 1B.

Referring to FIG. 1B, the preliminary stack structure 102 may be formed to include a vertically alternating (e.g., in the Z-direction) sequence of insulative structures 104 and additional insulative structures 106 arranged in tiers 108. Each of the tiers 108 of the preliminary stack structure 102 may include at least one (1) of the insulative structures 104 vertically neighboring at least one (1) of the additional insulative structures 106. The insulative structures 104 may be interleaved with the additional insulative structures 106. The insulative structures 104 of the preliminary stack structure 102 may be formed of and include insulative material. In some embodiments, the insulative structures 104 are formed of and include silicon dioxide (SiO₂).

The additional insulative structures 106 may be formed of and include additional insulative material that is different than, and that exhibits etch selectivity with respect to, the insulative material of the insulative structures 104. For example, the additional insulative structures 106 may individually be formed of and include dielectric nitride material (e.g., SiN_{y}) and/or oxynitride material (e.g., SiOₓN_{y}). In some embodiments, the additional insulative structures 106 are formed of and include Si₃N₄. The additional insulative structures 106 may serve as sacrificial structures for the subsequent formation of conductive structures, as described in further detail below.

In some embodiments, a number (e.g., quantity) of tiers 108 of the preliminary stack structure 102 is within a range of from thirty-two (32) to two hundred fifty-six (256) of the tiers 108. In some embodiments, the preliminary stack structure 102 includes one hundred twenty-eight (128) of the tiers 108. However, the disclosure is not so limited, and the preliminary stack structure 102 may include a different quantity of the tiers 108. In addition, in some embodiments, the preliminary stack structure 102 overlies a deck structure comprising additional tiers 108 of insulative structures 104 and the additional insulative structures, separated from the preliminary stack structure 102 by dielectric material, such as an interdeck insulative material.

With continued reference to FIG. 1B, the microelectronic device structure 100 further includes a source tier 110 vertically underlying (e.g., in the Z-direction) the preliminary stack structure 102. The source tier 110 may comprise, for example, a first conductive material 112 and a second conductive material 114. In some embodiments, the first conductive material 112 comprises conductively doped silicon. In some such embodiments, the second conductive material 114 is formed of and includes one or more of a metal silicide material (e.g., tungsten silicide (WSiₓ)), a metal nitride material (e.g., tungsten nitride), and a metal silicon nitride material (e.g., tungsten silicon nitride (WSiₓN_{y})). In some embodiments, the second conductive material 114 comprises tungsten silicide.

The dielectric material 116, which may serve as a mask material, may vertically overlie (e.g., in the Z-direction) a vertically uppermost tier 108 of the insulative structures 104 and the additional insulative structures 106 of the preliminary stack structure 102. The dielectric material 116 may comprise one or more of the materials described above with reference to the insulative structures 104 (e.g., SiO₂).

In some embodiments, the source tier 110 is formed to include one or more source structures 118 (e.g., a source plate, source lines) horizontally extending into a horizontal area of the staircase region 105. The source structures 118 may be operatively associated with vertically extending strings of memory cells within a memory array region of the microelectronic device structure 100, as described in further detail below. The source structures 118 may be formed of and include the first conductive material 112 and the second conductive material 114, and may be electrically isolated from other portions of the first conductive material 112 and the second conductive material 114 (e.g., other portions employed as conductive routing structures 117 and/or as conductive pad structures) by insulative material 119.

As shown in FIG. 1B, the staircase structure 120 may be formed within the staircase region 105 of the preliminary stack structure 102. Dielectric fill material 126 may be formed to fill at least one valley 124 (e.g., space, gap, trench, opening) vertically overlying the staircase structure 120. The dielectric fill material 126 may be formed of and include material exhibiting etch selectivity with respect to one or more of the dielectric material 116, the insulative structures 104, the additional insulative structures 106, as well as additional materials (e.g., additional insulative materials, additional conductive materials) formed during subsequent processing of the microelectronic device structure 100. In some embodiments, the dielectric fill material 126 comprises insulative material, such as one or more of the materials described above with reference to the insulative structures 104 (e.g., SiO₂).

The staircase structure 120 may be formed to include steps 122 comprising edges (e.g., horizontal ends) of the tiers 108 of the insulative structures 104 and additional insulative structures 106. For example, individual steps 122 may include an uppermost insulative structure 104a and an uppermost additional insulative structure 106a overlying the uppermost insulative structure 104a. Although FIG. 1B illustrates two (2) of the tiers 108 of the insulative structures 104 and the additional insulative structures 106 corresponding to one (1) step 122 of the staircase structure 120, the quantity of steps 122 of the staircase structure 120 may correspond to the quantity of tiers 108, such that a single (e.g., only one) step 122 corresponds to one of the tiers 108. The staircase structure 120 (and the valley 124 at least partially defined by the staircase structure 120) include a stepped cross-sectional profile in the ZY-plane, as shown in FIG. 1B. The stepped cross-sectional profile of the staircase structure 120 (and of the valley 124) may be defined by the geometric configurations of the steps 122 of the staircase structure 120.

For clarity and case of understanding the drawings and associated description, FIG. 1B illustrates only a particular quantity of steps 122 in the staircase structure 120. However, it will be understood that the staircase structure 120 may include a greater quantity of steps 122 than those illustrated. For example, the staircase structure 120 may include greater or equal to eight (8) of the steps 122, greater than or equal to sixteen (16) of the steps 122, greater or equal to than thirty-two (32) of the steps 122, greater than or equal to sixty-four (64) of the steps 122, greater than or equal to one-hundred twenty-eight (128) of the steps 122, or greater than or equal to two-hundred fifty-six (256) of the steps 122.

In some embodiments, the staircase structure 120 forms a portion of a stadium structure including opposing staircase structures 120 each having steps 122 defined by horizontal ends of the tiers 108 of the preliminary stack structure 102. In some such embodiments, multiple (e.g., more than one) stadium structures individually including one or more initial staircase structures are formed to be positioned at substantially the same elevations (e.g., vertical locations) as one another within the preliminary stack structure 102. During formation of the steps 122 of the staircase structure 120, an initial staircase structure (e.g., configured substantially similar to the staircase structure 120) may be formed at an upper vertical position within the preliminary stack structure 102 within horizontal boundaries (e.g., horizontal areas) of the staircase region 105 of the microelectronic device structure 100 using conventional processes (e.g., conventional photolithographic patterning processes, conventional material removal processes), and conventional processing equipment, which are not described in detail herein.

The microelectronic device structure 100 may then be subjected to one or more additional material removal processes (e.g., one or more chopping processes) to increase the depth(s) (e.g., in the Z-direction) of the initial staircase structure relative to an upper surface of the preliminary stack structure 102 and form the staircase structure 120. The staircase structure 120 may be substantially similar to the initial staircase structure used to form the staircase structure 120, except located at a relatively lower vertical position within the microelectronic device structure 100 (e.g., within the preliminary stack structure 102). The additional material removal processes may permit a lower boundary of the staircase structure 120 to be positioned at or below a lower boundary of the preliminary stack structure 102.

Prior to forming the dielectric fill material 126, implant regions 128 may be formed within the uppermost additional insulative structures 106a of the preliminary stack structure 102. An initial material (e.g., silicon nitride material) of exposed portions of the uppermost additional insulative structure 106a at each step 122 of the staircase structure 120 may, for example, be implanted with boron, carbon, oxygen, gallium, or a combination thereof to form the implant regions 128. One or more process acts may be performed to form the implant regions 128 of the uppermost additional insulative structure 106a. For example, the initial material of the uppermost additional insulative structure 106a may be subjected to (e.g., exposed to) one or more treatment acts that change a material composition of the uppermost additional insulative structure 106a. The treatment acts may change a material composition of the exposed portions of the uppermost additional insulative structure 106a compared to a material composition of remaining (e.g., unexposed) portions of the uppermost additional insulative structure 106a, as well the additional insulative structures 106 vertically underlying (e.g., in the Z-direction) the uppermost additional insulative structure 106a, as initially formed.

The material of the implant regions 128 of the uppermost additional insulative structure 106a may, for example, be formed of and include one or more of carbon-containing material (e.g., carbon-doped silicon nitride, silicon carbon nitride (SiCN)), boron-containing material (e.g., boron-doped silicon nitride), or gallium-containing material. By way of non-limiting example, the material of the implant regions 128 may be formed of and include one or more of boron nitride (BN_{y}), gallium nitride (GaN), oxynitride material (e.g., SiOₓN_{y}), and carboxynitride material (e.g., SiOₓC_{z}N_{y}). In some embodiments, the implant regions 128 comprise boron-doped nitride material or carbon-doped nitride material.

The implant regions 128 may exhibit etch selectivity relative to the dielectric material 116, the dielectric fill material 126, the insulative structures 104 of the preliminary stack structure 102, and, optionally, the additional insulative structures 106. As used herein, the term “selectively etchable” means and includes a material that exhibits a greater etch rate responsive to exposure to a given etch chemistry relative to another material exposed to the same etch chemistry. For example, the material may exhibit an etch rate that is at least about three times (3×) greater than the etch rate of another material, such as about five times (5×) greater than the etch rate of another material, such as an etch rate of about ten times (10×) greater, about twenty times (20×) greater, or about forty times (40×) greater than the etch rate of the another material. Etch chemistries and etch conditions for selectively etching a desired material may be selected by a person of ordinary skill in the art.

The implant conditions and the dopant concentration may be tailored to achieve the desired etch selectivity of the insulative structures 104 and other exposed materials relative to the implant regions 128. For example, the implant conditions may be formulated to achieve a desired etch selectivity of the implant regions 128, such that material of the implant regions 128 is selectively removable during material removal processes used to remove the additional insulative structures 106, including the remaining portions of the uppermost additional insulative structure 106a, of the preliminary stack structure 102. Accordingly, the additional insulative structures 106 and the implant regions 128 may be subsequently removed in a single processing act, responsive to the implant conditions used to form the implant regions 128. In additional embodiments, the implant regions 128 exhibit etch electivity relative to the additional insulative structures 106, such that the additional insulative structures 106 and the implant regions 128 are subsequently removed in multiple (e.g., two or more) processing acts.

The implant regions 128 may be formed within the uppermost additional insulative structure 106a of the vertically uppermost tier 108 of the insulative structures 104 and the additional insulative structures 106, without being formed within the additional insulative structures 106 of additional tiers 108 vertically underlying the vertically uppermost tier 108. The implant regions 128 may be formed to vertically overlie (e.g., in the Z-direction) and directly contact the uppermost insulative structure 104a of the vertically uppermost tier 108 of the staircase structure 120. Once formed, the implant regions 128 may horizontally extend across (e.g., in the Y-direction) and substantially cover upper surfaces of the uppermost insulative structure 104a of the individual steps 122. The remaining (e.g., unexposed) portions of the uppermost additional insulative structure 106a at the individual steps 122 may be adjacent to (e.g., laterally adjacent to) and in physical contact with the implant regions 128. As shown in FIG. 1B, the implant regions 128 may be formed to include sacrificial portions of the dielectric material formulated to be removed during subsequent processing acts. As will be described herein, the implant regions 128 may be replaced with another material (e.g., conductive material of strapping structures 166 (FIG. 1G)).

Still referring to FIG. 1B, following formation of the staircase structure 120, the openings 130 (e.g., contact openings) may be formed to vertically extend through the preliminary stack structure 102. Portions of each of the dielectric fill material 126, the implant regions 128, the insulative structures 104, and the additional insulative structures 106 are removed by exposing the respective materials to wet etch chemistries and/or dry etch chemistries, for example, in one or more material removal processes. Portions of the material of the implant regions 128 (e.g., central portions thereof) may be removed (e.g., etched) in one or more material removal processes resulting in a dimension (e.g., width) of each of the openings 130 being relatively less than that of the implant regions 128 of the uppermost additional insulative structure 106a (e.g., corresponding to upper surfaces of the steps 122 of the staircase structure 120). Further, the openings 130 extend beyond the upper surfaces of the steps 122 of the staircase structure 120 and through the materials of the preliminary stack structure 102.

Accordingly, the openings 130 may be formed to extend from an upper surface of the dielectric fill material 126 to the source tier 110 underlying the preliminary stack structure 102. As shown in FIG. 1B, the openings 130 extend entirely through a vertical extent (e.g., a height) of the preliminary stack structure 102. Thus, a height of each of the openings 130 in the vertical direction (e.g., the Z-direction) may be substantially similar to (e.g., substantially the same as) one another irrespective of horizontal orientation relative to the steps 122 of the staircase structure 120. Manufacturing processes may be simplified by forming the openings 130 to extend entirely through the vertical extent of the preliminary stack structure 102, without forming the openings 130 to extend to varying (e.g., differing) depths corresponding to various locations of the individual steps 122 of the staircase structure 120.

The first conductive material 112 of the source tier 110 may act as an etch stop material during removal of each of the dielectric fill material 126, the implant regions 128, the insulative structures 104, and the additional insulative structures 106, and formation of the openings 130. In some such embodiments, the openings 130 terminate within the source tier 110, such as at or within the first conductive material 112 at the processing stage depicted in FIG. 1B. In other embodiments, the openings 130 terminate at or within an insulative material overlying the first conductive material 112. In additional embodiments, the openings 130 extend through the first conductive material 112 and terminate at or within the second conductive material 114. By way of non-limiting example, the openings 130 may terminate at or within the first conductive material 112 at the process stage shown in FIG. 1B, and the openings 130 may terminate at or within the second conductive material 114 through subsequent processing of the microelectronic device structure 100. As will be described herein, the openings 130 may be used to form conductive contacts (e.g., conductive contacts 164 (FIG. 1G)) in contact with conductive contact structures (e.g., the strapping structures 166 (FIG. 1G)) of the staircase structure 120.

A horizontal dimension (e.g., width) of each of the openings 130 may be relatively smaller than that of upper surfaces (e.g., treads) of the steps 122 of the staircase structure 120. For example, a width of the openings 130 may be within a range of from about 100 nanometers (nm) to about 500 nm, such as from about 100 nm to about 150 nm, from about 150 nm to about 250 nm, from about 250 nm to about 350 nm, or from about 350 nm to about 500 nm. However, the disclosure is not so limited and the width of the openings 130 may be different than those described above. In some embodiments, the width of the openings 130 is selected and tailored to effect a size and shape of one or more features to be formed in the microelectronic device structure 100, as will be described herein.

Referring next to FIG. 1C, prior to forming materials of the conductive contacts 164 (FIG. 1G) within the openings 130, lateral (e.g., in the X-direction, in the Y-direction) portions of the additional insulative structures 106 may be converted to another insulative material to isolate the additional insulative structures 106 from the materials of the conductive contacts 164. For example, an initial material (e.g., a silicon nitride material of the additional insulative structures 106) may be oxidized to form a liner material 134 (e.g., an inner liner material, an inner insulative material). Accordingly, the liner material 134 may be directly laterally adjacent to (e.g., continuous with) remaining portions of the additional insulative structures 106. In some such embodiments, the liner material 134 is formed of and includes an oxide material having a material composition that differs from that of the remaining portions of the additional insulative structures 106, although other materials of the liner material 134 may be contemplated, so long as the liner material 134 exhibits etch selectivity relative to surrounding materials.

Formation of the liner material 134 within recessed regions may result in formation of isolation regions 132 between the openings 130 and the remaining portions of the additional insulative structures 106, such that portions of the additional insulative structures 106 having a first material composition are relatively remote (e.g., isolated) from the openings 130 by the liner material 134 of the isolation regions 132 having a second, different material composition. Thus, process acts may be selected to provide (e.g., facilitate, promote) formation of the liner material 134 proximate the openings 130 for formation of the isolation regions 132 between the remaining portions of the horizontally neighboring additional insulative structures 106 and subsequently formed materials of the conductive contacts 164 (FIG. 1G) within the openings 130.

Alternatively, the lateral portions of the additional insulative structures 106 may be selectively removed through the openings 130 to form the recessed regions for formation of the isolation regions 132. By way of non-limiting example, exposed portions of the additional insulative structures 106 may be exposed to an etchant (e.g., a wet etchant) through the openings 130 to selectively remove portions of the additional insulative structures 106 with respect to the insulative structures 104. In some embodiments, the additional insulative structures 106 are exposed to phosphoric acid (H₃PO₄) to selectively remove portions of the additional insulative structures 106 proximate the openings 130.

After selectively removing portions of the additional insulative structures 106, the liner material 134 may be formed within the recessed regions proximate remaining portions of the additional insulative structures 106 without fully filling the openings 130. For example, the liner material 134 may be formed within the recessed regions to effectively “pinch off” and close (e.g., seal) the recessed regions immediately adjacent to the openings 130. The liner material 134 may be formed to extend between vertically neighboring insulative structures 104 proximate the recessed regions vacated by portions of the additional insulative structures 106, such that the liner material 134 substantially vertically fills portions of the recessed regions proximate the openings 130 without entirely filling the openings 130. The liner material 134 is formed by conventional techniques, such as one or more of in situ growth, CVD, ALD, and PVD using conventional processing equipment. In some embodiments, the liner material 134 is formed (e.g., deposited) using a single, continuous ALD process or a single, continuous CVD process.

The liner material 134 may be formed of and include one or more of the materials described above with reference to the insulative structures 104 (e.g., SiO₂). For example, the liner material 134 may be formed of and include insulative material that is different than, and that exhibits etch selectivity with respect to, one or more of the additional insulative structures 106 and the implant regions 128. In some embodiments, the liner material 134 is formed of and includes a single high quality silicon oxide material, such as an ALD SiOₓ. For example, the liner material 134 may be a substantially uniform and substantially conformal silicon oxide material (e.g., a substantially uniform and substantially conformal silicon dioxide material) so that substantially no voids are present in the liner material 134. The liner material 134 may, alternatively, be formed of and include one or more of silicon oxycarbide (SiOₓC_{y}), silicon oxynitride (SiOₓN_{y}), hydrogenated silicon oxycarbide (SiCₓO_{y}H_{z}), or silicon oxycarbonitride (SiOₓC_{y}N_{z}), for example.

As shown in FIG. 1C, one or more side surfaces (e.g., lateral side surfaces, horizontal side surfaces) of the isolation regions 132 may directly contact side surfaces of the remaining portions of the additional insulative structures 106 of the preliminary stack structure 102 along interfaces 136 (e.g., vertical interfaces). The implant regions 128 may individually exhibit a greater lateral extent (e.g., a width in the Y-direction) than a lateral extent of the isolation regions 132, as shown in FIG. 1C. In additional embodiments, side surfaces of the implant regions 128 are substantially aligned with side surfaces of the isolation regions 132 or, alternatively, at least some of the isolation regions 132 may individually exhibit a greater lateral extent than a lateral extent of the implant regions 128, so long as the implant regions 128 are separated from the isolation regions 132 by the remaining portions of the uppermost additional insulative structure 106a at each step 122 of the staircase structure 120.

Referring to FIG. 1D, remaining portions of the material of the implant regions 128 (FIG. 1C) of the uppermost additional insulative structure 106a may, optionally, be selectively removed (e.g., exhumed) to form lateral openings 131 (e.g., lateral recesses) in communication with (e.g., continuous with) the openings 130. For example, portions of the implant regions 128 overlying the steps 122 of the staircase structure 120 may be at least partially (e.g., substantially entirely) removed to form the lateral openings 131. Removing the implant regions 128 increases the horizontal width of the openings 130 in the preliminary stack structure 102, forming the lateral openings 131 laterally intervening between the remaining portions of the uppermost additional insulative structure 106a at each step 122 of the staircase structure 120 and the dielectric fill material 126. In additional embodiments, the remaining portions of the implant regions 128 remain in the staircase structure 120 at the processing stage of FIG. 1D and are removed (e.g., exhumed) during subsequent material removal processes (e.g., replacement gate processing acts), as described with reference to FIGS. 1E and 1F.

In some embodiments, the material (e.g., carbon-containing material, boron-containing material) of the implant regions 128 is removed by exposing the material to one or more etchants, such as wet etchants, through the openings 130. The wet etchants may include one or more of phosphoric acid, acetic acid, nitric acid, hydrochloric acid, aqua regia, or hydrogen peroxide. In some embodiments, the material of the implant regions 128 is removed by a phosphoric acid/acetic acid/nitric acid (PAN) etch chemistry. However, the disclosure is not so limited and the material of the implant regions 128 may be removed with other etchants and/or material removal processes (e.g., vapor phase removal processes, atomic layer removal processes). For example, the material of the implant regions 128 may be removed by performing a sequence of self-limiting processes of an atomic layer removal process to modify a surface of a material (e.g., the implant regions 128), followed by selective removal of the modified surface material. In additional embodiments, the material of the implant regions 128 is removed by a plasma etching process (e.g., an inductively coupled plasma (ICP) etching process) comprising one or more of hydrogen fluoride (HF), nitrogen trifluoride (NF₃), sulfur hexafluoride (SF₆), carbon tetrafluoride (CF₄), and another material. The material of the implant regions 128 may, optionally, be exposed to hydrogen (H₂), nitrogen (N₂), oxygen (O₂), argon (Ar), or a combination thereof. The material of the implant regions 128 may, alternatively, be removed by exposure to one or more dry etchants.

Forming the lateral openings 131 at least partially (e.g., substantially) removes the material of the implant regions 128 laterally surrounding the openings 130. For example, the staircase structure 120 may be substantially free of the implant regions 128 following formation of the lateral openings 131. Alternatively, portions of the material of the implant regions 128 may remain within the lateral openings 131. The implant regions 128 of the uppermost additional insulative structure 106a vertically adjacent (e.g., underlying) the dielectric fill material 126 and laterally surrounding the openings 130 may be locations designated for the lateral openings 131. Accordingly, the lateral openings 131 are partially defined by the dielectric fill material 126, the remaining portions of the uppermost additional insulative structure 106a, and the uppermost insulative structure 104a.

As shown in FIG. 1D, a first sacrificial material 138 may, optionally, be formed within one or more of the openings 130 and the lateral openings 131. In some embodiments, the first sacrificial material 138 is conformally formed within the openings 130 to be substantially continuous along a vertical dimension (e.g., a vertical height) of the preliminary stack structure 102, as well as within the lateral openings 131 to be substantially continuous along a horizontal dimension (e.g., a width) of the individual steps 122 of the staircase structure 120. In other embodiments, the first sacrificial material 138 is non-conformally formed within the openings 130 and the lateral openings 131. Accordingly, the first sacrificial material 138 may be formed to include varying (e.g., uneven) thicknesses throughout the openings 130 and the lateral openings 131. Further, the first sacrificial material 138 may be formed to include segmented (e.g., discontinuous) portions thereof, such that regions of the openings 130 and the lateral openings 131 include the first sacrificial material 138 and additional regions thereof do not include the first sacrificial material 138. In additional embodiments, the first sacrificial material 138 is formed within the openings 130 without being formed in the lateral openings 131, such as when the remaining portions of the implant regions 128 remain in the staircase structure 120 at the processing stage of FIG. 1D.

The first sacrificial material 138 may be formed of and include insulative material, such as dielectric nitride material. For example, the material of the first sacrificial material 138 may comprise one or more of the materials described above with reference to the additional insulative structures 106 (e.g., Si₃N₄). In other embodiments, the first sacrificial material 138 comprises conductive material (e.g., polysilicon). For example, the first sacrificial material 138 may be formed to include amorphous silicon or polycrystalline silicon. In some such embodiments, the first sacrificial material 138 is doped with one or more dopants, such as with at least one N-type dopant (e.g., one or more of arsenic, phosphorous, antimony, and bismuth) or at least one P-type dopant (e.g., one or more of boron, aluminum, and gallium).

The first sacrificial material 138 may be in contact with one or more (e.g., each) of the dielectric fill material 126, the insulative structures 104 and the additional insulative structures 106 of the preliminary stack structure 102, the liner material 134 of the isolation regions 132, and the first conductive material 112 of the source tier 110. Accordingly, the first sacrificial material 138 may be formed to extend from the upper surface of the dielectric fill material 126 to the source tier 110 underlying the preliminary stack structure 102 within the openings 130. The first sacrificial material 138 may terminate at or within the first conductive material 112. Further, formation of the first sacrificial material 138 within the lateral openings 131 may result in formation of additional portions of the uppermost additional insulative structure 106a overlying the uppermost insulative structure 104a of the insulative structures 104.

In some instances, voids 140 (e.g., gaps, seams) are formed within the first sacrificial material 138 during fabrication of the microelectronic device structure 100. The first sacrificial material 138 may include one or more of the voids 140 during formation thereof within the openings 130 exhibiting a high aspect ratio (HAR). Further, the voids 140 may be formed within the first sacrificial material 138 within the lateral openings 131. For example, the first sacrificial material 138 may include one or more of the voids 140 within the openings 130 and the lateral openings 131 as a result of material formation (e.g., non-conformal deposition) processes used to form the insulative material of the first sacrificial material 138. In some instances, the voids 140 are centrally located within the openings 130 and the lateral openings 131, as well as at intersections of the openings 130 and the lateral openings 131. At least some of the openings 130 and the lateral openings 131 may be substantially free of the voids 140, such that the openings 130 and the lateral openings 131 are substantially filled with the first sacrificial material 138, as shown for illustrative purposes in the opening 130 and the corresponding lateral opening 131 at the left-hand side of the microelectronic device structure 100 of FIG. 1D.

The first sacrificial material 138 may be configured and positioned to protect the materials (e.g., the dielectric fill material 126, the insulative structures 104, the liner material 134 of the isolation regions 132, the first conductive material 112 of the source tier 110) defining the openings 130 and the lateral openings 131 from being removed (e.g., exhumed) during the subsequent material removal processes of the preliminary stack structure 102. At least partially filling the openings 130 and lateral openings 131 with the first sacrificial material 138 may also substantially inhibit (e.g., impede, prevent) formation of additional dielectric material (e.g., carbon-containing mask material) during subsequent processing acts. Following formation of the first sacrificial material 138, the microelectronic device structure 100 may, optionally, be subjected to a chemical mechanical planarization (CMP) process to remove material (e.g., additional portions of the first sacrificial material 138) overlying the preliminary stack structure 102. Alternatively, the first sacrificial material 138 may not be formed at the processing stage of FIG. 1D, such that the openings 130 and the lateral openings 131 remain open during the subsequent processing acts (e.g., replacement gate processing acts).

Referring next to FIG. 1E, slots 144 (also referred to herein as “replacement gate slots”) may be formed through the preliminary stack structure 102 (FIG. 1D) to facilitate the replacement of the additional insulative structures 106 (FIG. 1D) with conductive structures, as well as selective removal of the first sacrificial material 138 (FIG. 1D), if present. As best shown in FIG. 1F, the additional insulative structures 106 may be at least partially (e.g., substantially) replaced with conductive structures 152 comprising conductive material 168 to form a stack structure 156 comprising tiers 158 of the conductive structures 152 vertically interleaved with the insulative structures 104 through so-called “replacement gate” or “gate last” processing acts. A second sacrificial material 150 may, optionally, be formed within the openings 130 and the lateral openings 131, such as in regions previously occupied by the first sacrificial material 138. The slots 144 may then be filled with dielectric material 148. Formation of the slots 144 and the conductive structures 152 is described in further detail below, along with additional components (e.g., structures, features) of the microelectronic device structure 100 at the processing stage depicted in FIG. 1E. FIG. 1F is a simplified, partial cross-sectional view of the microelectronic device structure 100 about the line F-F shown in FIG. 1E. For clarity and case of understanding of the drawings and related description, not all features depicted in one of FIGS. 1E and 1F are depicted in the other of FIGS. 1E and 1F.

As shown in FIG. 1E, in combination with FIG. 1F, the slots 144 may be formed to vertically extend (e.g., in the Z-direction) though the preliminary stack structure 102 (FIG. 1D), such as through the dielectric fill material 126 and the tiers 108 (FIG. 1D) of the insulative structures 104 and the additional insulative structures 106 (FIG. 1D). Portions of each of the dielectric fill material 126, the insulative structures 104, and the additional insulative structures 106 are removed by exposing the respective materials to wet etch chemistries and/or dry etch chemistries, for example, in one or more material removal processes.

Prior to formation of the slots 144, portions of the dielectric fill material 126 and the preliminary stack structure 102 may, optionally, be covered with an additional dielectric material (e.g., an additional portion of the dielectric material 116) and/or mask material 154 (e.g., carbon-containing mask material) configured and positioned to protect the dielectric fill material 126 from being removed (e.g., exhumed) during the material removal processes of the dielectric fill material 126 and the materials of the preliminary stack structure 102. While the slots 144 are illustrated as being formed after formation of the first sacrificial material 138 for clarity and case of understanding of the drawings and related description, the slots 144 may, alternatively, be formed before formation of the first sacrificial material 138. For example, the slots 144 may be formed during (e.g., substantially simultaneous with) formation of the openings 130.

The slots 144 may extend to the source tier 110, such as to the first conductive material 112. Alternatively, the slots 144 may terminate at or within an insulative material overlying the first conductive material 112. The slots 144 may separate (e.g., divide) the microelectronic device structure 100 into block structures 146. Although FIG. 1E illustrates only three (3) slots 144 and only two (2) block structures 146, the disclosure is not so limited. The microelectronic device structure 100 may include a plurality of (e.g., four, five, six, eight) block structures 146, each separated from laterally neighboring (e.g., in the X-direction) block structures 146 by one of the slots 144. The slots 144 may divide the microelectronic device structure 100 into any desired quantity of block structures 146.

Referring to FIG. 1F, the additional insulative structures 106 (FIG. 1D) may be selectively removed (e.g., exhumed) through the slots 144 (FIG. 1E). Further, the first sacrificial material 138 may be selectively removed (e.g., exhumed) through the slots 144. For example, the first sacrificial material 138 may be removed during (e.g., substantially simultaneous with) removal of the additional insulative structures 106. In embodiments including the implant regions 128 remaining in the staircase structure 120 at the processing stage of FIG. 1D, the remaining portions of the implant regions 128 may be selectively removed (e.g., exhumed) through the cell openings between the insulative structures 104 during (e.g., substantially simultaneous with) removal of the additional insulative structures 106 and the first sacrificial material 138 to reduce cost and the number of process acts conducted.

Accordingly, the additional insulative structures 106 of the preliminary stack structure 102 and the material (e.g., boron-doped or carbon-doped nitride material) of the implant regions 128 may be removed in a single processing act to form (e.g., reopen) the lateral openings 131 during formation of the cell openings between the insulative structures 104. In additional embodiments including the implant regions 128 exhibiting etch electivity relative to the additional insulative structures 106, the additional insulative structures 106 and the implant regions 128 are removed in multiple (e.g., two or more) processing acts. Spaces between vertically neighboring (e.g., in the Z-direction) insulative structures 104 may be filled with the conductive material 168 to form the conductive structures 152 and the stack structure 156 including the tiers 158 of the insulative structures 104 and the conductive structures 152.

In some embodiments, the conductive material 168 of the conductive structures 152 comprises tungsten (W). In other embodiments, the conductive material 168 of the conductive structures 152 comprises conductively doped polysilicon. In yet other embodiments, the conductive material 168 is formed to comprise one or more of titanium, ruthenium, aluminum, and molybdenum. For each of the conductive structures 152, the conductive material 168 thereof may be substantially homogeneous or may be substantially heterogeneous. In some embodiments, each of the conductive structures 152 is substantially homogeneous. In additional embodiments, at least one of the conductive structures 152 is substantially heterogeneous.

At least one vertically (e.g., in the Z-direction) lower conductive structure 152 of the stack structure 156 may be employed as at least one lower select gate (e.g., at least one source side select gate (SGS)) of the microelectronic device structure 100. In some embodiments, a single (e.g., only one) conductive structure 152 of a vertically lowermost tier 158 of the stack structure 156 is employed as a lower select gate (e.g., a SGS) of the microelectronic device structure 100. In addition, vertically (e.g., in the Z-direction) upper conductive structure(s) 152 of the stack structure 156 may be employed as upper select gate(s) (e.g., drain side select gate(s) (SGDs)) of the microelectronic device structure 100. In some embodiments, horizontally neighboring conductive structures 152 of a vertically uppermost tier 158 of the stack structure 156 (e.g., separated from each other by slots) are employed as upper select gates (e.g., SGDs) of the microelectronic device structure 100. In some embodiments, more than one (e.g., two, four, five, six) conductive structures 152 are employed as upper select gates (e.g., SGDs) of the microelectronic device structure 100.

During formation of the conductive material 168 of the conductive structures 152, additional portions of the conductive material 168 may, optionally, be formed within the openings 130 and the lateral openings 131 to form the second sacrificial material 150 without fully filling the openings 130 and the lateral openings 131. For example, the conductive material 168 of the second sacrificial material 150 may be formed through the slots 144 (FIG. 1E) and the cell openings between the insulative structures 104 during formation of the conductive structures 152. Accordingly, the second sacrificial material 150 includes substantially the same material composition as the conductive structures 152 (e.g., the conductive material 168).

As shown in FIG. 1F, the second sacrificial material 150 may include first portions 150a within the openings 130 and second portions 150b within the lateral openings 131. For example, the first portions 150a may vertically extend (e.g., in the Z-direction) within the openings 130, and the second portions 150b may horizontally extend (e.g., in the X-direction, in the Y-direction) within the lateral openings 131. The second sacrificial material 150 may be formed to include a substantially continuous material within the openings 130 and the lateral openings 131, as shown in FIG. 1F. In additional embodiments, the second sacrificial material 150 is formed to include varying (e.g., uneven) thicknesses throughout one or more of the openings 130 and the lateral openings 131. Further, the second sacrificial material 150 may be formed to include segmented (e.g., discontinuous) portions thereof, such that regions of the openings 130 and the lateral openings 131 include the second sacrificial material 150 and additional regions thereof do not include the second sacrificial material 150.

The second sacrificial material 150 may, in some instances, include additional voids (e.g., gaps, seams) therewithin. In some embodiments, the second sacrificial material 150 (e.g., the first portions 150a) is formed on the vertical side surfaces of the dielectric fill material 126, without additional portions of the second sacrificial material 150 (e.g., the second portions 150b) being formed within the lateral openings 131, as shown for illustrative purposes in the lateral opening 131 at the left-hand side of the microelectronic device structure 100 of FIG. 1F. Since the uppermost additional insulative structure 106a (FIG. 1D) at each step 122 is laterally adjacent to (e.g., at an elevational level of) the lateral openings 131, one of the conductive structures 152 (e.g., an uppermost conductive structure 152a) may partially define the lateral openings 131 at the processing stage of FIGS. 1E and 1F.

The second sacrificial material 150 may or may not remain within the microelectronic device structure 100. For example, remaining portions of the conductive material 168 of the first portions 150a of the second sacrificial material 150 may remain on vertical side surfaces of the dielectric fill material 126, and the materials of the stack structure 156, without the conductive material 168 of the second portions 150b thereof remaining within the lateral openings 131. In some embodiments, remaining portions of the conductive material 168 of the second portions 150b of the second sacrificial material 150 within the lateral openings 131 are removed using one or more material removal processes. If present, remaining portions of dielectric material (e.g., High-K dielectric material 172 (FIG. 1I)) within the lateral openings 131 may also be removed using additional material removal processes (e.g., wet etching).

Further, features of the array region of the microelectronic device structure 100 may be formed during (e.g., substantially simultaneous with) formation of corresponding features of the staircase region 105, as described above with reference to FIG. 1A. For example, after forming the conductive structures 152 of the stack structure 156 within the staircase region 105 and the array region, end portions of the conductive structures 152 adjacent to the slots 144 within the array region may be recessed (e.g., laterally recessed) relative to end portions of the insulative structures 104, and conductive rails may be formed adjacent to the conductive structures 152 in the tiers 158. The conductive rails may be formed horizontally adjacent (e.g., horizontally on) at least the conductive structures 152 within the recessed regions. By recessing the end portions of the conductive structures 152 and forming the conductive rails within the recessed regions, electrical resistance of the microelectronic device structure 100 may be lower.

In some embodiments, the remaining portions of the conductive material 168 of the second portions 150b of the second sacrificial material 150 are removed from within the lateral openings 131 within the staircase region 105 during material removal processes used to form the recessed regions of the conductive structures 152 within the array region. For example, the material removal processes used to remove the second portions 150b of the second sacrificial material 150 (e.g., the conductive material 168) may be conducted during (e.g., substantially simultaneous with) the material removal processes used to recess the end portions of the conductive structures 152 adjacent to the slots 144 within the array region. Accordingly, a lateral extent (e.g., a width) of the lateral openings 131 may include substantially the same size as a lateral extent of the recessed regions of the conductive structures 152 within the array region. By way of non-limiting example, the lateral extent of each of the lateral openings 131 and the recessed regions of the conductive structures 152 may individually be within a range of from about 20 nm to about 50 nm.

During formation of the conductive material 168 of the second sacrificial material 150 and the conductive structures 152, upper regions of the openings 130 may remain open, such that the second sacrificial material 150 does not substantially fill the openings 130 and the lateral openings 131. In some embodiments, a so-called “punch through” etch is then performed to remove portions of the second sacrificial material 150 and the first conductive material 112 and expose the underlying portions of the second conductive material 114 or, alternatively, remove portions of the second sacrificial material 150 and an insulative material overlying the first conductive material 112 and expose the underlying portions of the first conductive material 112.

As shown in FIG. 1F, one or more side surfaces (e.g., lateral side surfaces, horizontal side surfaces) of the isolation regions 132 may directly contact side surfaces of the conductive structures 152 of the stack structure 156 along interfaces 160 (e.g., vertical interfaces). The presence of the liner material 134 provides the isolation regions 132 between the conductive contacts 164 (FIG. 1G) and the conductive structures 152, such that the conductive structures 152 are remote (e.g., isolated) from the conductive contacts 164 by the isolation regions 132. After forming the conductive material 168 of the second sacrificial material 150 and the conductive structures 152 of the stack structure 156, the slots 144 (FIG. 1E) may be filled with the dielectric material 148 (FIG. 1E).

The dielectric material 148 may be formed of and include insulative material, such as one or more of dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). A material composition of the dielectric material 148 may be substantially the same as a material composition of one or more of the dielectric fill material 126 and the insulative structures 104 of the stack structure 156, or the material composition of the dielectric material 148 may be different than the material composition of the dielectric fill material 126 and the insulative structures 104. In some embodiments, the dielectric material 148 is formed of and includes SiO₂.

Referring next to FIG. 1G, conductive fill material 162 may be formed within the openings 130 (FIG. 1F) to form the conductive contacts 164. Once formed, each of the conductive contacts 164 may vertically extend completely through the stack structure 156 without terminating on the steps 122 of the staircase structure 120, as shown in FIG. 1G. For example, the conductive contacts 164 may vertically extend (e.g., in the Z-direction) from a vertically uppermost boundary of the dielectric fill material 126 (e.g., at an elevational level of a vertically uppermost tier 158 of the stack structure 156) to or beyond a vertically uppermost boundary of the second conductive material 114 of the source tier 110. In some embodiments, the staircase structure 120 is substantially free of conductive contacts formed to terminate on the steps 122 thereof.

As shown in FIG. 1G, presence of the liner material 134 within the recessed regions provides the isolation regions 132 between the conductive contacts 164 and additional conductive structures 152 underlying each of the uppermost conductive structures 152a, such that the additional conductive structures 152 are remote (e.g., isolated) from the conductive contacts 164 by the isolation regions 132.

At least some of the conductive contacts 164 may exhibit a different geometric configuration (e.g., one or more different dimensions, a different shape) and/or different horizontal spacing than at least some other of the conductive contacts 164, or each of the conductive contacts 164 may exhibit substantially the same geometric configuration (e.g., the same dimensions and the same shape) and horizontal spacing (e.g., in the Y-direction) as each of the other conductive contacts 164. For example, individual conductive contacts 164 of the microelectronic device structure 100 may exhibit a height (e.g., in the Z-direction) that is substantially similar to a height of each other of the conductive contacts 164.

Each of the conductive contacts 164 of the microelectronic device structure 100 may be formed to extend entirely through the vertical extent of the stack structure 156 and to terminate at the single location in order to substantially reduce (e.g., substantially prevent) damage within the staircase structure 120 during fabrication. Accordingly, manufacturing processes may be simplified by forming the conductive contacts 164 to extend entirely through the vertical extent of the stack structure 156 and to terminate at a single location (e.g., at or within the source tier 110), without forming the conductive contacts 164 to extend to varying (e.g., differing) depths of the individual steps 122 of the staircase structure 120. In contrast, conventional microelectronic device structures include conductive contacts that terminate (e.g., land on) upper surfaces of individual steps of staircase structures, resulting in varying heights of conductive contacts throughout the staircase structures.

In some instances, damage may occur within the staircase structures during fabrication of conventional microelectronic device structures. Particularly, damage to the tier materials of the tiers, also called “clipping,” may be a source of defect, which can adversely affect memory device performance. In addition, misaligned conductive contacts that terminate on upper surfaces of the individual steps of staircase structures, may be susceptible to bridging (e.g., shorting, electrical connection) between neighboring portions of the conductive structures 152. Further, terminating the conductive contacts at varying (e.g., differing) depths of the steps of the staircase structure of conventional microelectronic device structures may result in so-called “overetch” or “underetch” during processing. Accordingly, each of the conductive contacts 164 of the microelectronic device structure 100 may be formed to extend entirely through the vertical extent of the stack structure 156 and to terminate at the single location in order to substantially reduce (e.g., substantially prevent) damage within the staircase structure 120 during fabrication.

During formation of the conductive contacts 164, the conductive fill material 162 thereof may also substantially fill the lateral openings 131 (FIG. 1F) to form the strapping structures 166. The conductive contacts 164 may be integral and continuous (e.g., unitary) with the strapping structures 166. The strapping structures 166 may horizontally project outward from the conductive contacts 164. The conductive fill material 162 of the strapping structures 166 may be in contact with each of the dielectric fill material 126, the insulative structures 104 (e.g., the uppermost insulative structure 104a), and the conductive material 168 of the conductive structures 152 of the stack structure 156. After forming the conductive contacts 164 and the strapping structures 166, the microelectronic device structure 100 may be subjected to a CMP process to remove sacrificial material outside of the boundaries of the openings 130 (FIG. 1F).

In some embodiments, the conductive fill material 162 of the conductive contacts 164 and the strapping structures 166 is formed adjacent to remaining portions of the second sacrificial material 150, if present, within the openings 130 (FIG. 1F) and the lateral openings 131 (FIG. 1F). For example, the conductive fill material 162 may substantially fill a remainder of the openings 130 and the lateral openings 131 and be at least partially (e.g., substantially) laterally surrounded by the second sacrificial material 150. In other embodiments, the second sacrificial material 150 is substantially removed prior to forming the conductive fill material 162 of the conductive contacts 164 and the strapping structures 166. In some such embodiments, the conductive fill material 162 substantially fills the openings 130 and is in contact with the dielectric fill material 126, the liner material 134 of the isolation regions 132, and the insulative structures 104 of the stack structure 156, as well as the first conductive material 112 and the second conductive material 114 of the source tier 110. Accordingly, the conductive contacts 164 may be formed to extend from the upper surface of the dielectric fill material 126 to the source tier 110 underlying the stack structure 156. The conductive contacts 164 may terminate at or within the second conductive material 114 of the source tier 110. Alternatively, the conductive contacts 164 may terminate at or within the first conductive material 112. In such embodiments, the conductive contacts 164 are formed to be self-aligned with the underlying conductive materials (e.g., the first conductive material 112) using a so-called “assisted self-alignment” process.

The conductive contacts 164 and the strapping structures 166 may individually be formed of and include conductive material (e.g., the conductive fill material 162). By way of non-limiting example, the conductive contacts 164, and the strapping structures 166 may be formed of and include one or more of polysilicon, tungsten, titanium, titanium nitride, or another material. In some embodiments, the conductive fill material 162 comprises polysilicon. In some such embodiments, the conductive fill material 162 is doped with one or more dopants, such as with at least one N-type dopant (e.g., one or more of arsenic, phosphorous, antimony, and bismuth) or at least one P-type dopant (e.g., one or more of boron, aluminum, and gallium). In other embodiments, the conductive fill material 162 of the conductive contacts 164 and the strapping structures 166 comprises tungsten. The conductive fill material 162 may or may not include substantially the same material composition as the conductive material 168 of the second sacrificial material 150 and the conductive structures 152 of the stack structure 156.

The strapping structures 166 may be considered portions (e.g., outwardly horizontally projecting portions) of the conductive contacts 164. For example, as shown in FIG. 1G, the conductive contacts 164 may individually include a first portion 164a in electrical communication with the source tier 110, such as with the second conductive material 114 thereof, without being in electrical communication with all of the conductive structures 152 of the stack structure 156 vertically underlying (e.g., in the Z-direction) the individual steps 122 of the staircase structure 120. In addition, the conductive contacts 164 may also individually include a second portion 164b, corresponding to one of the strapping structures 166, in electrical communication with the first portion 164a thereof and with the conductive material 168 of one of the conductive structures 152. For example, the uppermost conductive structure 152a of the conductive structures 152 defining each step 122 may be configured as a contact region for the second portion 164b of each of the conductive contacts 164. The size and location of the first portion 164a may correspond to the size and location of the openings 130 (FIG. 1F), and the size and location of the second portion 164b may correspond to the size and location of the lateral openings 131 (FIG. 1F).

Accordingly, an individual conductive contact 164 may be configured to facilitate electrical communication between the source tier 110 and the uppermost conductive structure 152a defining an individual step 122 of the staircase structure 120. Further, the strapping structure 166 of at least one of the conductive contacts 164 is vertically offset from the strapping structure 166 of at least one other of the conductive contacts 164. Forming the conductive contacts 164 to facilitate electrical communication between the source tier 110 and the conductive structures 152 may reduce a quantity of support structures (e.g., support pillars) within the staircase region 105. For example, facilitating electrical communication between the source tier 110 and the conductive structures 152 through the conductive contacts 164 facilitates forming the support structures proximate the conductive contacts 164 without the need to form complex conductive pathways above the stack structure 156. Accordingly, a greater quantity of the steps 122 of the staircase structure 120 may be provided within a given area of the microelectronic device structure 100 as compared to conventional microelectronic device structure configurations. By providing the conductive contacts 164 (including the first portions 164a and the second portions 164b thereof) within the staircase structure 120, such configurations may also permit reduced congestion in conductive pathways above the stack structure 156. By reducing congestion in conductive pathways above the stack structure 156, spacing of the conductive features may be increased, resulting in a decrease in parasitic (e.g., stray) capacitance between adjacent conductive features during use and operation of the microelectronic device structure 100.

By forming the strapping structures 166 during formation of the conductive contacts 164, manufacturing processes may be simplified and costs may be reduced. The strapping structures 166 (e.g., the conductive fill material 162 thereof) may be formed during (e.g., substantially simultaneous with) formation of the conductive contacts 164 using a single, continuous CVD process or a single, continuous PVD process, for example, without forming the strapping structures 166 using an ALD process, similar to that used during the replacement gate process acts. Additionally, the methods and structures of the disclosure may reduce the risk of damage during the formation of devices of the disclosure and may effectuate increased yield and decreased current leakage (e.g., which may otherwise result from undesirable damage) as compared to conventional methods, conventional structures, and conventional devices.

FIG. 1H illustrates an enlarged portion of a top-down view of a portion of FIG. 1G, in accordance with the embodiment of the microelectronic device structure 100 of FIG. 1G. For clarity and ease of understanding the drawings and associated description, surrounding materials including the dielectric fill material 126 are not shown in FIG. 1H. The strapping structures 166 may laterally surround and physically contact portions (e.g., the first portions 164a) of the conductive contacts 164 at an elevational level of the uppermost conductive structure 152a of each step 122 of the staircase structure 120. Accordingly, the second portion 164b (also described herein as the strapping structures 166) of an individual conductive contact 164 may be located horizontally proximate to and may at least partially (e.g., substantially) surround the first portion 164a thereof. The first portion 164a and the second portion 164b of the conductive contacts 164 may include substantially the same material composition with no readily discernable physical interface therebetween. Alternatively, the first portion 164a and the second portion 164b thereof may include a material composition that differs from one another, such that a material composition of the strapping structures 166 differs from a material composition of the conductive contacts 164. In some embodiments, a material composition of the strapping structures 166 is substantially the same as a material composition of the conductive structures 152 of the stack structure 156, and a material composition of the conductive contacts 164 differs from the material composition of each of the strapping structures 166 and the conductive structures 152. The uppermost conductive structure 152a of the conductive structures 152 may be located horizontally proximate to (e.g., directly contact) and may at least partially (e.g., substantially) surround the strapping structures 166. The strapping structures 166 laterally intervene directly between the conductive contacts 164 and the uppermost conductive structures 152a of the stack structure 156.

The conductive contacts 164 may individually exhibit a substantially circular horizontal cross-sectional shape, as shown in the top-down view of FIG. 1H. However, the disclosure is not so limited. As a non-limiting example, in additional embodiments, the conductive contacts 164 individually exhibit a substantially rectangular cross-sectional shape (e.g., a substantially square cross-sectional shape), or a different elongate cross-sectional shape (e.g., an oblong cross-sectional shape).

As shown in FIG. 1H, each of the conductive contacts 164 and the strapping structures 166 may be horizontally centered within horizontal areas of the individual steps 122 of the staircase structure 120 (FIG. 1G), although other configurations may be contemplated. A lateral dimension (e.g., a second width W₂ in the Y-direction) of one or more of the steps 122 may be relatively larger than a lateral dimension (e.g., a first width W₁, a diameter in the Y-direction) of an individual conductive contact 164 (including and the first portion 164a and the second portion 164b thereof). By way of non-limiting example, the first width W₁ may be within a range of from about 300 nm to about 1000 nm (e.g., 1 μm), such as from about 300 nm to about 400 nm, from about 400 nm to about 500 nm, from about 500 nm to about 600 nm, from about 600 nm to about 700 nm, from about 700 nm to about 800 nm, from about 800 nm to about 900 nm, or from about 900 nm to about 1000 nm. However, the disclosure is not so limited and the first width W₁ may be different than those described above.

In some embodiments, the second width W₂ is within a range from about 1.5 times greater than the first width W₁ of the conductive contacts 164 to about 2.5 times the first width W₁ of the conductive contacts 164 at a lateral boundary of the second portion 164b at an elevational level of the uppermost conductive structure 152a. In some embodiments, the second width W₂ is at least about 2.0 times the first width W₁. For example, the second width W₂ may be within a range of from about 600 nm to about 1200 nm (e.g., 1.2 μm), such as from about 600 nm to about 800 nm, from about 800 nm to about 1000 nm, or from about 1000 nm to about 1200 nm. However, the disclosure is not so limited and the second width W₂ may be different than those described above. In some embodiments, the second width W₂ is about the same size as the first width W₁. In other embodiments, the second width W₂ is such that the lateral boundary of the second portion 164b of the conductive contacts 164 at an elevational level of the uppermost conductive structure 152a does not laterally extend beyond the steps 122 to reduce or prevent electrical shorting of the conductive contacts 164 to additional conductive structures 152 of the stack structure 156. The second width W₂ may be sized such that the conductive contacts 164 do not laterally extend beyond the lateral boundary of the steps 122.

FIG. 1I illustrates an enlarged portion of box I of FIG. 1G, in accordance with the embodiment of the microelectronic device structure 100 of FIG. 1G. For clarity and case of understanding the drawings and associated description, surrounding materials including the dielectric fill material 126 are not shown in FIG. 1I. As shown in FIG. 1I, the conductive structures 152 may, optionally, individually comprise conductive liner material 170 adjacent to the insulative structures 104 and the conductive material 168 in contact with the conductive liner material 170. Further, the conductive structures 152 may, optionally, comprise the High-K dielectric material 172 in contact with the insulative structures 104 and the conductive liner material 170. The conductive liner material 170 may be vertically interposed between the conductive material 168 and an insulative structure 104, and the High-K dielectric material 172 may be vertically interposed between the conductive liner material 170 and the insulative structure 104. For ease of illustration and understanding, the conductive liner material 170 and the High-K dielectric material 172 are illustrated within some of the spaces between the vertically neighboring insulative structures 104 in FIG. 1I, but it will be understood that the microelectronic device structure 100 may include the conductive liner material 170 and, optionally, the High-K dielectric material 172 within additional (e.g., each of the) spaces between the vertically neighboring insulative structures 104. The conductive structures 152 may be located at locations corresponding to the locations of the additional insulative structures 106 (FIG. 1D) removed through the slots 144 (FIG. 1E).

As shown in FIG. 1I, lateral side surfaces of the strapping structures 166 may be laterally adjacent and in physical contact with lateral side surfaces of the uppermost conductive structure 152a along interfaces 174 (e.g., vertical interfaces) to improve metal-to-metal contact therebetween. The High-K dielectric material 172 may be formed adjacent to the conductive structures 152, without the High-K dielectric material 172 being formed within the lateral openings 131 (FIG. 1F) of the strapping structures 166. Forming the High-K dielectric material 172 adjacent to the conductive structures 152 without forming the High-K dielectric material 172 within the lateral openings 131 may facilitate formation of the strapping structures 166 without the need to remove portions of the High-K dielectric material 172 from lateral side surfaces of the uppermost conductive structure 152a prior to forming the conductive fill material 162 of the strapping structures 166 in order to substantially reduce (e.g., substantially prevent) damage to surrounding materials (e.g., the uppermost insulative structure 104a) within the staircase structure 120.

Since the strapping structures 166 are formed laterally adjacent to and directly contacting the uppermost conductive structure 152a, the conductive liner material 170 and the High-K dielectric material 172 do not laterally intervene between the strapping structures 166 and the uppermost conductive structure 152a. Accordingly, the strapping structures 166 may be formed directly adjacent to (e.g., in the X-direction, in the Y-direction) the uppermost conductive structure 152a of the individual steps 122. In some such embodiments, only an outer side surface of each of the strapping structures 166 is in physical contact with any of the conductive structures 152 of the stack structure 156. Alternatively, at least one material (e.g., the conductive liner material 170) may horizontally intervene between the strapping structures 166 and the uppermost conductive structure 152a. In either instance, the strapping structures 166 may be formed directly adjacent to the uppermost conductive structure 152a.

The conductive liner material 170 (if formed) surrounding the conductive structures 152 may be formed of and include, for example, one or more seed materials from which the conductive material 168 may be formed. The conductive liner material 170 may be formed of and include, for example, one or more of at least one metal (e.g., titanium, tantalum), at least one metal nitride (e.g., tungsten nitride, titanium nitride, tantalum nitride), or at least one additional material. In some embodiments, the conductive liner material 170 comprises titanium nitride (TiNₓ). The High-K dielectric material 172 may, for example, be formed from aluminum oxide, hafnium oxide, zirconium oxide, tantalum oxide, a combination thereof, or a combination of silicon oxide and one or more of the listed materials. In some embodiments, the High-K dielectric material 172 is formed from hafnium-doped silicon dioxide, where the ratio of hafnium to silicon is controlled to achieve a desired etch selectivity of the High-K dielectric material 172.

Since each of the conductive contacts 164 vertically extend completely through the stack structure 156 (FIG. 1G), the conductive contacts 164 vertically extend through the steps 122 of the staircase structure 120 without terminating at upper surfaces thereof. As shown in FIG. 1I, the liner material 134 within the isolation regions 132 horizontally intervenes between the conductive contacts 164 and the additional conductive structures 152 aligned below the uppermost conductive structure 152a, such that the additional conductive structures 152 are remote (e.g., isolated) from the conductive contacts 164 by the isolation regions 132. For example, the conductive contacts 164 may extend through the dielectric fill material 126 to individually contact the uppermost conductive structure 152a and the steps 122 of the staircase structure 120, without contacting the additional conductive structures 152 thereunder. Each step 122 may individually be in contact (e.g., physical contact, electrical contact) with one of the conductive contacts 164 through the second portion 164b thereof (also described as one of the strapping structures 166). The second portion 164b of each conductive contact 164 may be configured (e.g., sized and shaped) to maximize (e.g., increase) contact area with the contact region of the uppermost conductive structure 152a along the interface 174.

In some embodiments, the conductive liner material 170 and/or the High-K dielectric material 172 are maintained (e.g., remain) adjacent to (e.g., above, below) the uppermost conductive structure 152a at each step 122 of the staircase structure 120. In other embodiments, the staircase structure 120 lacks the conductive liner material 170 and the High-K dielectric material 172 adjacent to the uppermost conductive structure 152a, and the dielectric fill material 126 is directly adjacent to (e.g., horizontally adjacent to, vertically adjacent to) the conductive material 168 of the uppermost conductive structure 152a. The conductive liner material 170 and the High-K dielectric material 172, if present, may laterally (e.g., in the X-direction, in the Y-direction) and vertically (e.g., in the Z-direction) surround portions of the uppermost conductive structure 152a of the individual steps 122, and the uppermost conductive structure 152a may vertically overlie (e.g., directly overlie) the uppermost insulative structure 104a. Thus, the strapping structures 166 are vertically adjacent to (e.g., directly contact) the uppermost insulative structure 104a, and the strapping structures 166 laterally extend across portions of the uppermost insulative structure 104a at the individual steps 122 of the staircase structure 120.

As shown in FIG. 1I, the conductive structures 152 underlying the uppermost conductive structures 152a may be separated from the first portions 164a of the conductive contacts 164, by the isolation regions 132, by a distance D₁ in the Y-direction. By way of non-limiting example, the distance D₁ may be within a range of from about 20 nm to about 100 nm, such as from about 20 nm to about 40 nm, from about 40 nm to about 60 nm, from about 60 nm to about 80 nm, or from about 80 nm to about 100 nm. In some embodiments, the distance D₁ is about 80 nm, which corresponds to a horizontal width of the liner material 134 within the isolation regions 132 in the Y-direction. Further, the horizontal width of the liner material 134 may vary along a vertical height of each of the conductive structures 152.

The conductive material 168 of the uppermost conductive structure 152a may have a first thickness T₁ (e.g., height) in the vertical direction within a range of from about 10 nm to about 30 nm, such as from about 10 nm to about 15 nm, from about 15 nm to about 20 nm, or from about 20 nm to about 25 nm, or from about 25 nm to about 30 nm. The second portions 164b of the conductive contacts 164 (also described herein as the strapping structures 166) may individually have a second thickness T₂ (e.g., height) in the vertical direction within a range of from about 10 nm to about 40 nm, such as from about 10 nm to about 15 nm, from about 15 nm to about 20 nm, from about 20 nm to about 25 nm, or from about 25 nm to about 40 nm. However, the disclosure is not so limited and the first thickness T₁ and the second thickness T₂ may be different than those described above. In some embodiments, the second thickness T₂ is within a range of from about 15 nm to about 20 nm, which corresponds to a thickness of the implant regions 128 (FIG. 1C), although other thicknesses may be contemplated. In embodiments including the conductive liner material 170 and the High-K dielectric material 172 adjacent to (e.g., above, below) the uppermost conductive structure 152a, the second thickness T₂ of the strapping structures 166 may be relatively larger than the first thickness T₁ of the conductive material 168 of the uppermost conductive structure 152a. In some embodiments, the second thickness T₂ is larger than the first thickness T₁ by about 2 nm to about 4 nm, for example. Alternatively, the second thickness T₂ substantially the same as (e.g., substantially equal to) the first thickness T₁, such as when the staircase structure 120 lacks the conductive liner material 170 and the High-K dielectric material 172 adjacent to the uppermost conductive structure 152a.

The second thickness T₂ of the strapping structures 166 may be tailored to have a desired value that may be selected at least partially based on design requirements of the microelectronic device structure 100. Specifically, the shape of the conductive contacts 164 and the strapping structures 166 may facilitate an increased contact region with the uppermost conductive structure 152a of the individual steps 122. For example, the size, shape, and orientation of the strapping structures 166 may facilitate an increased surface area available for contact with the uppermost conductive structure 152a. As a result, the RC (product of resistance and capacitance) of the conductive contacts 164 and the strapping structures 166 may be improved, which may correlate to an increase in the performance of a device containing the microelectronic device structure 100 by facilitating a reduction in operational speed (e.g., programming time). The presence of the High-K dielectric material 172 adjacent to the uppermost conductive structure 152a may result in a decrease in parasitic (e.g., stray) capacitance between adjacent conductive features during use and operation of the microelectronic device structure 100.

A lateral dimension (e.g., a third width W₃, a diameter in the Y-direction) of the liner material 134 of the isolation regions 132 may be relatively less than a lateral dimension (e.g., a fourth width W₄, a diameter in the Y-direction) of the strapping structures 166, corresponding to the first width W₁ of an individual conductive contact 164 (FIG. 1H). In some embodiments, the third width W₃ of the liner material 134 of the isolation regions 132 is within a range of from about 120 nm to about 500 nm, such as from about 120 nm to about 200 nm, from about 200 nm to about 300 nm, from about 300 nm to about 400 nm, or from about 400 nm to about 500 nm. Accordingly, the conductive structures 152 may individually be separated from the conductive contacts 164 by a distance in the Y-direction within a range of from about 20 nm to about 100 nm, such as from about 20 nm to about 40 nm, from about 40 nm to about 60 nm, from about 60 nm to about 80 nm, or from about 80 nm to about 100 nm.

The fourth width W₄ of strapping structures 166 may be within a range of from about 300 nm to about 1000 nm, such as from about 300 nm to about 400 nm, from about 400 nm to about 500 nm, from about 500 nm to about 600 nm, from about 600 nm to about 700 nm, from about 700 nm to about 800 nm, from about 800 nm to about 900 nm, or from about 900 nm to about 1000 nm. Accordingly, the uppermost conductive structure 152a at each step 122 may individually be separated from the conductive contacts 164 by a distance in the Y-direction within a range of from about 20 nm to about 120 nm, such as from about 20 nm to about 40 nm, from about 40 nm to about 60 nm, from about 60 nm to about 80 nm, from about 80 nm to about 100 nm, or from about 100 nm to about 120 nm. In other embodiments, the third width W₃ is substantially the same as (e.g., substantially equal to) the fourth width W₄.

In additional embodiments, the third width W₃ is relatively greater than the fourth width W₄, such that at least some (e.g., each) of the isolation regions 132 individually exhibit a greater lateral extent than a lateral extent of the strapping structures 166. For example, the uppermost conductive structure 152a at each step 122 may individually be separated from the conductive contacts 164 by a distance in the Y-direction within a range of from about 10 nm to about 50 nm. Since the High-K dielectric material 172 may be formed adjacent to the conductive structures 152, without being formed within the lateral openings 131 (FIG. 1F) of the strapping structures 166, the High-K dielectric material 172 may be separated from the conductive contacts 164 by a distance in the Y-direction within a range of from about 10 nm to about 50 nm, for example.

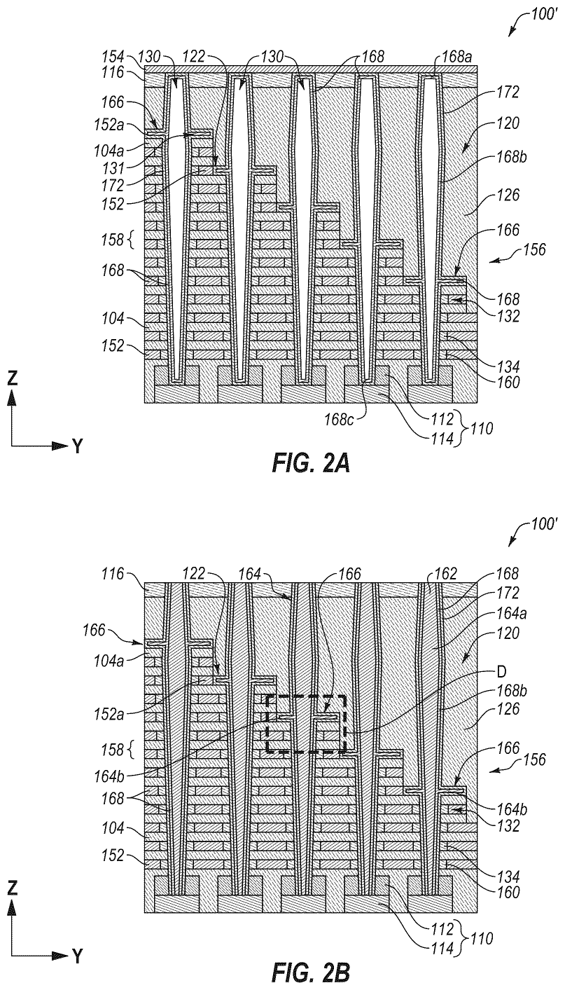

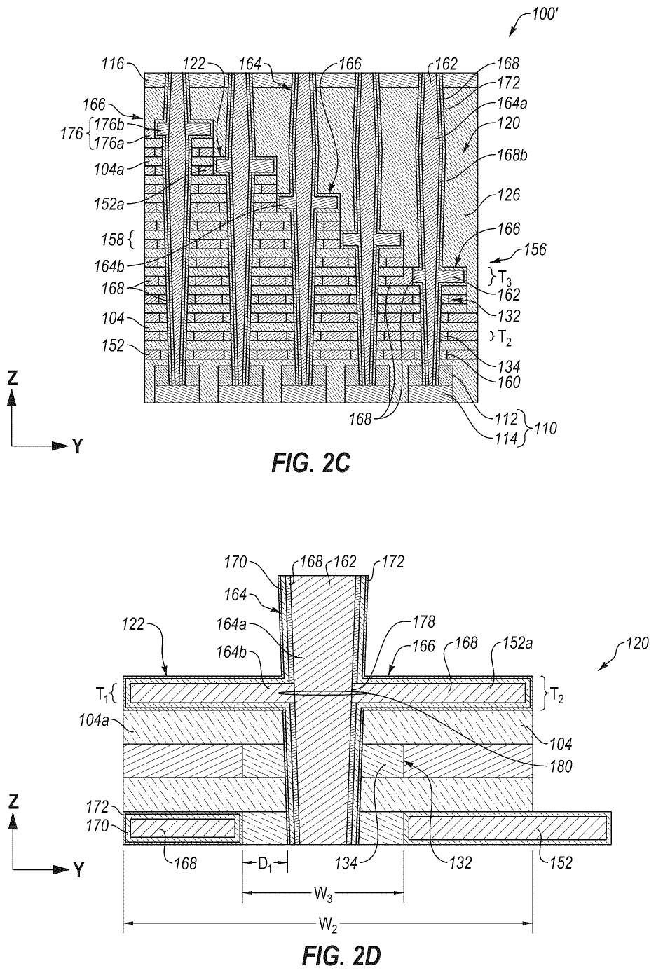

One of ordinary skill in the art will appreciate that, in accordance with additional embodiments of the disclosure, the features and feature configurations described above in relation to FIGS. 1A through 1I may be adapted to design needs of different microelectronic devices (e.g., different memory devices) depending on desired electrical performance properties of the microelectronic devices. By way of non-limiting example, in accordance with additional embodiments of the disclosure, and FIGS. 2A through 2D are simplified, partial cross-sectional views of a method of forming a microelectronic device structure having a different configuration than the microelectronic device structure 100. Throughout the remaining description and the accompanying figures, functionally similar features (e.g., structures, devices) are referred to with similar reference numerals. To avoid repetition, not all features shown in FIGS. 2A through 2D are described in detail herein. Rather, unless described otherwise below, a feature designated by a reference numeral of a previously described feature (whether the previously described feature is first described before the present paragraph, or is first described after the present paragraph) will be understood to be substantially similar to the previously described feature.

FIG. 2A is a simplified, partial cross-sectional view of a microelectronic device structure 100′ (e.g., a memory device, such as a 3D NAND Flash memory device). At the processing stage depicted in FIG. 2A, the microelectronic device structure 100′ may be substantially similar to the microelectronic device structure 100 at the processing stage depicted in FIG. 1F. At the processing stage depicted in FIG. 2B, the microelectronic device structure 100′ may be substantially similar to the microelectronic device structure 100 at the processing stage depicted in FIG. 1G. FIG. 2C illustrates an additional embodiment of the microelectronic device structure 100′ at the process stage of FIG. 2B. FIG. 2D illustrates an enlarged portion of the cross-sectional view of box D of FIG. 2B.

The microelectronic device structure 100′ illustrated in FIG. 2A includes the stack structure 156, and the openings 130 vertically extending through the dielectric fill material 126 and the materials of the stack structure 156 following the replacement gate processing acts. The stack structure 156 of the microelectronic device structure 100′ may also be formed to include the vertically alternating (e.g., in the Z-direction) sequence of the insulative structures 104 and the conductive structures 152 arranged in the tiers 158. The stack structure 156 may be formed to vertically overlie the source tier 110 including the first conductive material 112 and the second conductive material 114. The microelectronic device structure 100′ may include the staircase structure 120 including the steps 122, the dielectric fill material 126 overlying the staircase structure 120. The dielectric material 116 may, optionally, be formed to vertically overlie the stack structure 156. As shown in FIG. 2A, the microelectronic device structure 100′ may be formed to include the isolation regions 132 including the liner material 134 laterally adjacent to and directly contacting the side surfaces of the conductive structures 152 along the interfaces 160.

The microelectronic device structure 100′ may also be formed to include the lateral openings 131 in communication with the openings 130, as in processing stage of the embodiment of the disclosure previously described with reference to FIG. 1F. However, as shown in FIG. 2A, configurations of the materials within the openings 130 and the lateral openings 131 may be modified relative to the configurations thereof previously described with reference to FIG. 1F to include additional materials, as described in further detail below.

At the processing stage of FIG. 2A, the microelectronic device structure 100′ may be formed to include the High-K dielectric material 172 laterally adjacent to the dielectric fill material 126 and the materials of the stack structure 156, and the conductive material 168 at least partially (e.g., substantially) surrounded by the High-K dielectric material 172. For example, the High-K dielectric material 172 may be formed within one or more (e.g., each) of the openings 130 and the lateral openings 131 during formation of the High-K dielectric material 172 within the cell openings between the insulative structures 104 during the replacement gate processing acts.

During formation of the conductive material 168 and, optionally, the conductive liner material 170 (FIG. 2D) within the cell openings to form the conductive structures 152, additional portions of the conductive material 168 and the conductive liner material 170, if formed, may be formed within the openings 130 without fully filling the openings 130. Accordingly, the openings 130 of the embodiment of FIG. 2A may include the High-K dielectric material 172, the conductive material 168, and, optionally, the conductive liner material 170 therewithin. In addition, the lateral openings 131 may include the High-K dielectric material 172, the conductive material 168, and the conductive liner material 170 therewithin, as described below. For convenience, only the conductive material 168 is illustrated as being formed within the openings 130 and the lateral openings 131 in FIGS. 2A through 2C, although it is understood that the conductive liner material 170 may, optionally, be formed to facilitate formation of the conductive material 168.

As shown in FIG. 2A, the conductive material 168 within the openings 130 may include a first portion 168a (e.g., an upper portion), a second portion 168b (e.g., a vertical portion), and a third portion 168c (e.g., a lower portion) thereof. Accordingly, the openings 130 may be defined by the conductive material 168 at the processing stage of FIG. 2A. To facilitate formation of the High-K dielectric material 172 and the conductive material 168 within the openings 130, an additional portion of the dielectric material 116 and/or an additional mask material (e.g., the mask material 154) may be configured and positioned to enclose (e.g., seal) the openings 130 during the replacement gate processing acts. For example, the upper regions of the openings 130 may be closed during the material removal processes used to remove the additional insulative structures 106 (FIG. 1D) of the preliminary stack structure 102 (FIG. 1D) and during formation of the conductive structures 152.

The strapping structures 166 of the embodiment of FIG. 2A may be formed within the lateral openings 131 at an earlier processing stage than a processing stage of the previous embodiment. For example, the strapping structures 166 may be formed during formation of the conductive material 168 used to form the conductive structures 152 of the stack structure 156 prior to forming the conductive fill material 162 (FIG. 2B) of the conductive contacts 164 (FIG. 2B) within the openings 130. Accordingly, the strapping structures 166 may be formed during (e.g., substantially simultaneous with) formation of the conductive structures 152 during the replacement gate processing acts. In particular, the High-K dielectric material 172 and the conductive material 168 of the strapping structures 166 may be formed through the slots 144 (FIG. 1E) and the cell openings between the insulative structures 104 during formation of the conductive structures 152. The High-K dielectric material 172 may be substantially continuous throughout the cell openings of the conductive structures 152 and the lateral openings 131 of the strapping structures 166. The strapping structures 166 may be formed of the conductive material 168 and may include substantially the same material composition as the conductive structures 152. The conductive material 168 of the strapping structures 166 and the conductive material 168 of the uppermost conductive structure 152a may include substantially the same material composition with no readily discernable physical interface therebetween.

Alternatively, central portions of the lateral openings 131 may remain open (e.g., unoccupied) at the processing stage of FIG. 2A. For example, the High-K dielectric material 172 and the conductive material 168 may be formed within the openings 130 during formation of the conductive structures 152 without fully filling the lateral openings 131, and the central portions of the lateral openings 131 may be filled with the conductive fill material 162 (FIG. 2B) during formation of the conductive contacts 164 (FIG. 2B). In some such embodiments, the High-K dielectric material 172 and the conductive material 168 are formed within portions of the lateral openings 131 during (e.g., substantially simultaneous with) formation of the materials within the openings 130, and the conductive fill material 162 may subsequently be formed within the central portions of the lateral openings 131 during formation of the conductive fill material 162 within the central portions of the openings 130 at the processing stage of FIG. 2B.

Following formation of the conductive material 168, the microelectronic device structure 100′ may be subjected to a CMP process to remove material (e.g., the additional portions of the dielectric material 116, the mask material 154) overlying the stack structure 156. Additionally, portions of the conductive material 168 (e.g., the first portion 168a) and portions of the High-K dielectric material 172 at the upper regions of the openings 130 may be removed during the CMP process to form (e.g., reopen) the openings 130. A punch through etch may then be performed to remove additional portions (e.g., the third portion 168c) of the conductive material 168 and additional portions of the High-K dielectric material 172 and expose the underlying portions of the second conductive material 114 or, alternatively, remove portions of the conductive material 168, the High-K dielectric material 172, and an insulative material overlying the first conductive material 112 and expose the underlying portions of the first conductive material 112. Accordingly, remaining materials adjacent to lower regions of the openings 130 may indicate that the punch through etch was performed to remove the additional portions of the conductive material 168 and the High-K dielectric material 172. Alternatively, the conductive material 168 (e.g., the first portion 168a, the third portion 168c) and the High-K dielectric material 172 may be selectively removed by exposing the respective materials to wet etch chemistries and/or dry etch chemistries, for example, in one or more material removal processes, which may, optionally, result in removal of portions (e.g., an entirety) of the respective materials including the second portion 168b along lateral side surfaces of the dielectric fill material 126 and the materials of the stack structure 156 defining the openings 130.

Referring to FIG. 2B, following formation of the High-K dielectric material 172 and the conductive material 168 within the openings 130 (FIG. 2A) and the lateral openings 131 (FIG. 2A), the conductive fill material 162 may be formed within the openings 130 to form the conductive contacts 164. Once formed, each of the conductive contacts 164 may vertically extend completely through the stack structure 156 without terminating on the steps 122 of the staircase structure 120, as shown in FIG. 2B. The conductive fill material 162 of the conductive contacts 164 may be formed laterally adjacent to (e.g., directly laterally adjacent to) the conductive material 168 of the strapping structures 166. The conductive fill material 162 may or may not include substantially the same material composition as the conductive material 168 of the strapping structures 166 and the conductive structures 152 of the stack structure 156. In embodiments including the central portions of the lateral openings 131 remaining open (e.g., unoccupied) at the processing stage of FIG. 2A, the conductive fill material 162 may be formed within the central portions of the lateral openings 131 to form the strapping structures 166 during (e.g., substantially simultaneous with) formation of the conductive contacts 164. If formed within the lateral openings 131, the conductive fill material 162 of the strapping structures 166 may be laterally adjacent to and at least partially (e.g., substantially) surrounded by one or more of the conductive material 168 and the High-K dielectric material 172.

As shown in FIG. 2B, the High-K dielectric material 172 and the conductive material 168 may remain within the microelectronic device structure 100′, such that the High-K dielectric material 172 at least partially (e.g., substantially) surrounds the conductive material 168, and the conductive material 168 at least partially (e.g., substantially) surrounds the conductive fill material 162 of the conductive contacts 164. In additional embodiments, one or more (e.g., each) of the High-K dielectric material 172 and the conductive material 168 initially formed within the openings 130 (FIG. 2A) and/or the lateral openings 131 (FIG. 2A) is removed and the conductive fill material 162 of the conductive contacts 164 is in contact with the dielectric fill material 126 and the materials of the stack structure 156, as in the previous embodiment.

By forming the conductive material 168 within the openings 130, the upper regions of the openings 130 (FIG. 2A) may be restricted (e.g., effectively isolated) during the replacement gate processing acts to facilitate formation of the strapping structures 166 during formation of the conductive structures 152 of the stack structure 156. Thus, the strapping structures 166 may be formed during formation of the conductive structures 152 to reduce cost and the number of process acts conducted. Since the openings 130 are restricted during the replacement gate processing acts using the conductive material 168, further mask material used to protect the materials of the openings 130 during subsequent processing of the microelectronic device structure 100′ may not be formed to reduce cost and the number of process acts conducted.

Referring to FIG. 2C, the microelectronic device structure 100′ may be formed to include features (e.g., structures, materials) substantially similar to the features (e.g., structures, materials) of the microelectronic device structure 100′ up to and including the processing stage previously described with reference to FIG. 2B. For example, the microelectronic device structure 100′ of FIG. 2C may be formed to include the stack structure 156 comprising the tiers 158 of the conductive structures 152 vertically interleaved with the insulative structures 104. The conductive contacts 164 individually include the first portion 164a in electrical communication with the source tier 110 and the second portion 164b, corresponding to one of the strapping structures 166, in electrical communication with the first portion 164a thereof at the individual steps 122 of the staircase structure 120.

The conductive contacts 164 and the strapping structures 166 may respectively be substantially similar to and may be formed in substantially the same manner as the conductive fill material 162 of the conductive contacts 164, the conductive material 168 of the conductive structures 152 and the strapping structures 166, and the High-K dielectric material 172 of the microelectronic device structure 100′ up to and including the processing stage previously described with reference to FIG. 2B. Accordingly, the method of forming the microelectronic device structure 100′ up to and including the processing stage depicted in FIG. 2C may be similar to the processing stages and features previously described in relation to the formation of the microelectronic device structure 100′ up to and including the processing stage previously described with reference to FIG. 2B.

Additional processes (e.g., material formation processes) may, optionally, be used to form multiple thickness of the strapping structures 166 of FIG. 2C. In the previous embodiment of FIG. 2B, the strapping structures 166 may be formed to exhibit the second thickness T₂ (FIG. 2D) that is substantially uniform (e.g., substantially consistent) along a lateral dimension of the strapping structures 166. In the embodiment of FIG. 2C, the strapping structures 166 may be formed to have multiple (e.g., two or more) thicknesses along the lateral dimension thereof. For example, the treads of the individual steps 122 of the staircase structure 120 may include conductive pad structures 176 individually including a first portion 176a having the second thickness T₂ and a second portion 176b having a third thickness T₃, relatively larger than the second thickness T₂ of the first portion 176a. In some embodiments, the second thickness T₂ of the first portion 176a corresponds to a thickness of the conductive structures 152 (e.g., within a range of from about 15 nm to about 20 nm). The third thickness T₃ of the second portion 176b may be within a range from about 1.5 times greater than the second thickness T₂ of the first portion 176a to about 3 times (e.g., about 2 times) the second thickness T₂ of the first portion 176a. However, the disclosure is not so limited and the second thickness T₂ and the third thickness T₃ may be different than those described above.

As shown in FIG. 2C, the first portion 176a of the conductive pad structures 176 may be laterally adjacent to (e.g., directly contact) the uppermost conductive structure 152a, and the second portion 176b may be laterally adjacent to (e.g., directly contact) the first portion 176a. The conductive contacts 164 are individually laterally separated from the first portion 176a by portions of the second portion 176b. Further, the uppermost conductive structure 152a at one of the steps 122 is laterally separated from the second portion 176b by the first portion 176a. Alternatively, the uppermost conductive structure 152a may be laterally adjacent to (e.g., directly contact) the second portion 176b, without the first portion 176a intervening therebetween. In some embodiments, the conductive pad structures 176, including each of the first portion 176a and the second portion 176b, include the conductive fill material 162 of the conductive contacts 164, without including the High-K dielectric material 172, and the conductive material 168 of the conductive structures 152. In other embodiments, the first portion 176a and portions of the second portion 176b adjacent thereto include the conductive material 168 of the uppermost conductive structure 152a, and additional portions of the second portion 176b at ends of the steps 122 include the conductive fill material 162 of the conductive contacts 164, as shown for illustrative purposes in the strapping structure 166 at the right-hand side of the microelectronic device structure 100′ of FIG. 2C. In some such embodiments, the first portion 176a and the portions of the second portion 176b adjacent thereto include the High-K dielectric material 172.

The first portion 176a and the second portion 176b of the conductive pad structures 176 may individually form a generally “L-shaped” structure of the strapping structures 166 at the individual steps 122. As shown in FIG. 2C, the second portion 176b having the relatively larger thickness (e.g., the third thickness T₃) substantially surrounds the conductive contacts 164. In some embodiments, lateral end surfaces of the second portion 176b and lateral end surfaces of the underlying uppermost insulative structure 104a are substantially vertically aligned (e.g., substantially coplanar) with one another. In other embodiments, the second portion 176b laterally extends beyond horizontal boundaries of at least one of the steps 122 of the staircase structure 120 directly vertically thereunder, such that the lateral end surfaces of the second portion 176b extend beyond the lateral end surfaces of the uppermost insulative structure 104a, so long as the strapping structures 166 are isolated from additional strapping structures 166 of adjacent steps 122 by at least some distance (e.g., equal to or greater than about 20 nm).

The multiple thicknesses of the conductive pad structures 176 may be formed in order to substantially reduce (e.g., substantially prevent) damage within the staircase structure 120 during fabrication. For example, prior to conducting the replacement gate processing acts, the additional insulative structures 106 (FIG. 1D) of the preliminary stack structure 102 (FIG. 1D) may be formed to include dielectric pad structures (e.g., so called “mesa nitride” structures) on the additional insulative structures 106 (e.g., dielectric nitride structures) at the steps 122 of the staircase structure 120. During the replacement gate processing, the dielectric pad structures are also replaced with the conductive material 168 to effectively increase thicknesses of portions of the uppermost conductive structure 152a at the steps 122 of the staircase structure 120 and mitigate damage within the staircase structure 120. In addition, the shape of the strapping structures 166 including the multiple thicknesses of the conductive pad structures 176 may facilitate an increased contact region with the conductive contacts 164 at the steps 122. For example, the relatively larger thickness of the second portion 176b of the conductive pad structures 176 may facilitate an increased surface area available for contact with the lateral side surfaces of the conductive contacts 164. As a result, the RC (product of resistance and capacitance) of the conductive contacts 164 and the strapping structures 166 may be improved.

While the conductive contacts 164 and the strapping structures 166 including the conductive pad structures 176 of FIG. 2C are illustrated as being formed in substantially the same manner as the processing stages of FIGS. 2A and 2B for clarity and case of understanding of the drawings and related description, the conductive contacts 164 and the conductive pad structures 176 of the strapping structures 166 of FIG. 2C may, alternatively, be formed in substantially the same manner as the processing stages of FIGS. 1A through 1I. For example, the conductive pad structures 176 of the strapping structures 166 may be formed to include the conductive fill material 162 formed during formation of the conductive contacts 164, without including the conductive material 168 and the High-K dielectric material 172 formed during formation of the conductive structures 152.

FIG. 2D illustrates an enlarged portion of box D of FIG. 2B, in accordance with the embodiment of the microelectronic device structure 100′ of FIG. 2B. For clarity and ease of understanding the drawings and associated description, surrounding materials including the dielectric fill material 126 are not shown in FIG. 2D. As in the previous embodiment, the conductive structures 152 of FIG. 2D may include the conductive material 168 and, optionally, one or more of the conductive liner material 170 and the High-K dielectric material 172. Since the strapping structures 166 are formed during formation of the conductive structures 152, the strapping structures 166 also include the conductive material 168 and, optionally, the conductive liner material 170 and the High-K dielectric material 172. For example, the High-K dielectric material 172 may at least partially (e.g., substantially) surround the conductive material 168 of the strapping structures 166. Further, the High-K dielectric material 172 may at least partially (e.g., substantially) laterally surround the conductive material 168 of the conductive contacts 164.

In some embodiments, the High-K dielectric material 172 is formed to include varying (e.g., uneven) thicknesses, such that the conductive contacts 164 and the strapping structures 166 are only partially surrounded by the High-K dielectric material 172. In other embodiments, substantially continuous portions of the High-K dielectric material 172 surrounds the conductive material 168 of each of the conductive contacts 164 and the strapping structures 166, as shown in FIG. 2D. For example, at least a majority (e.g., greater than 50 percent, such as greater than or equal to about 75 percent, greater than or equal to about 90 percent, or greater than or equal to about 99 percent) of the conductive material 168 of each of the conductive contacts 164 and the strapping structures 166 is substantially surrounded by the High-K dielectric material 172. The High-K dielectric material 172 may substantially (e.g., entirely) surround the strapping structures 166 on three (3) consecutive sides including upper surfaces, lower surfaces, and outer lateral side surfaces thereof. The presence of the High-K dielectric material 172 adjacent to the uppermost conductive structure 152a and the strapping structures 166 may result in a decrease in parasitic (e.g., stray) capacitance between adjacent conductive features during use and operation of the microelectronic device structure 100′.

As shown in FIG. 2D, lateral side surfaces of the conductive contacts 164 may be laterally adjacent and in physical contact with inner lateral side surfaces of the strapping structures 166 along interfaces 178 (e.g., vertical interfaces) to improve metal-to-metal contact therebetween. Since the conductive contacts 164 are formed laterally adjacent to and directly contacting the strapping structures 166, the conductive liner material 170 and the High-K dielectric material 172 do not laterally (e.g., horizontally) intervene between the conductive contacts 164 and the strapping structures 166. Accordingly, portions of the conductive contacts 164 may be formed directly adjacent to (e.g., in the X-direction, in the Y-direction) the strapping structures 166 of the individual steps 122. Alternatively, at least one material (e.g., the conductive liner material 170) may horizontally intervene between the conductive contacts 164 and the strapping structures 166. In either instance, the conductive contacts 164 may be formed directly adjacent to the strapping structures 166.

In some instances, regions 180 (e.g., lateral seams) of the conductive fill material 162 of the conductive contacts 164 are formed within the strapping structures 166 during fabrication of the microelectronic device structure 100′. The regions 180 may be a product of material formation (e.g., deposition) processes used to form the conductive fill material 162 of the conductive contacts 164. For example, the regions 180 may include laterally extending seams within portions (e.g., central portions) of the strapping structures 166 adjacent to (e.g., substantially surrounding) the conductive contacts 164, as shown in FIG. 2D. The regions 180 may be responsive, at least in part, to portions of the conductive material 168 being formed within the openings 130 (FIG. 2A) of the conductive contacts 164 during formation of the conductive material 168 of the conductive structures 152. The regions 180 of the conductive fill material 162 may horizontally project outward relative to adjacent (e.g., vertically extending) portions of the conductive fill material 162 within the conductive contacts 164 as a result of the conductive material 168 being formed prior to forming the conductive fill material 162 of the conductive contacts 164.

One or more of the High-K dielectric material 172 and the conductive liner material 170 may be vertically interposed between the uppermost conductive structure 152a and the uppermost insulative structure 104a. Further, one or more of the High-K dielectric material 172 and the conductive liner material 170 may be horizontally interposed between the conductive contacts 164 and the insulative structures 104 (e.g., the uppermost insulative structure 104a) vertically underlying the strapping structures 166 and horizontally interposed between the conductive contacts 164 and the dielectric fill material 126 vertically overlying the strapping structures 166.

As shown in FIG. 2D, the first portion 164a and the second portion 164b of the conductive contacts 164 may include a material composition that differs from one another, such that a material composition of the strapping structures 166 (corresponding to the second portion 164b) differs from a material composition of the conductive contacts 164 (e.g., the first portion 164a). The conductive fill material 162 of the conductive contacts 164 may be formed directly adjacent to the conductive material 168 of the strapping structures 166. Alternatively, in embodiments including the conductive fill material 162 being formed within the central portions of the lateral openings 131 (FIG. 2A) to form the strapping structures 166 during formation of the conductive contacts 164, each of the conductive contacts 164 and the strapping structures 166 may include the conductive fill material 162 within the central portions thereof.

As in the previous embodiment, the first thickness T₁ of the conductive material 168 may be relatively less than the second thickness T₂ of the strapping structures 166 including the conductive liner material 170 and the High-K dielectric material 172. Since the strapping structures 166 of FIG. 2D are formed during formation of the conductive structures 152, each of the first thickness T₁ of the conductive material 168 and the second thickness T₂ of the strapping structures 166 are substantially uniform (e.g., substantially consistent) along a lateral dimension of the strapping structures 166.

As shown in FIG. 2D, a lateral dimension (e.g., width) of an individual conductive contact 164, including and the first portion 164a and the second portion 164b is substantially the same as (e.g., substantially equal to) the second width W₂ of the steps 122. Thus, the strapping structures 166 are vertically adjacent to (e.g., directly contact) the uppermost insulative structure 104a, and the strapping structures 166 fully laterally extend across the uppermost insulative structure 104a at the individual steps 122 of the staircase structure 120. By way of non-limiting example, the width of the conductive contacts 164 may be within a range of from about 600 nm to about 1200 nm, such as from about 600 nm to about 800 nm, from about 800 nm to about 1000 nm, or from about 1000 nm to about 1200 nm. The third width W₃ of the liner material 134 of the isolation regions 132 is relatively less than an additional width of the strapping structures 166, corresponding to the second width W₂ of the steps 122. Accordingly, the strapping structures 166 exhibit a relatively larger area at each step 122 of the staircase structure 120 of the microelectronic device structure 100′ as compared to conventional microelectronic device structure configurations. As a result, the RC (product of resistance and capacitance) of the conductive contacts 164 and the strapping structures 166 may be improved, which may correlate to an increase in the performance of a device containing the microelectronic device structure 100′. The presence of the High-K dielectric material 172 adjacent to the uppermost conductive structure 152a may result in a decrease in parasitic (e.g., stray) capacitance between adjacent conductive features during use and operation of the microelectronic device structure 100′.

FIG. 3 illustrates a simplified, partial cutaway perspective view of a portion of a microelectronic device 201 (e.g., a memory device, such as a dual deck 3D NAND Flash memory device) including a microelectronic device structure 200. The microelectronic device structure 200 may be substantially similar to the microelectronic device structures 100, 100′ following the processing stage previously described with reference to FIGS. 1G and 2B. As shown in FIG. 3, the microelectronic device structure 200 may include a staircase structure 220 (e.g., including the staircase structure 120 (FIGS. 1G and 2B)) defining contact regions for connecting conductive contacts 206 (e.g., corresponding to the conductive contacts 164 (FIGS. 1G and 2B)) directly to conductive tiers 205 (e.g., conductive layers, conductive plates, such as the conductive structures 152 (FIGS. 1G and 2B)). The microelectronic device structure 200 may include vertically extending strings 207 of memory cells 203 that are coupled to each other in series. The vertically extending strings 207 may extend vertically (e.g., in the Z-direction) and orthogonally to data lines 202, a source tier 204 (e.g., corresponding to the source tier 110 (FIGS. 1G and 2B)), the conductive tiers 205, first select gates 208 (e.g., upper select gates, drain select gates (SGDs)), select lines 209, and a second select gate 210 (e.g., a lower select gate, a source select gate (SGS)). The microelectronic device 201 may include multiple blocks 232 (e.g., corresponding to the block structures 146 (FIG. 1E)) horizontally separated (e.g., in the X-direction) from one another by filled slot structures 230 (e.g., corresponding to the slots 144 (FIG. 1E) filled with the dielectric material 148 (FIG. 1E)).

Conductive contacts 213 and additional conductive contacts 211 may, optionally, electrically couple components to each other as shown. For example, the select lines 209 may be electrically coupled to the first select gates 208. The microelectronic device 201 may also include a control unit 212 positioned under and within a horizontal area of the memory array including the vertically extending strings 207 of memory cells 203. The control unit 212 may include control logic devices configured to control various operations of other features (e.g., the vertically extending strings 207 of memory cells 203) of the microelectronic device 201. By way of non-limiting example, the control unit 212 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers), decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. The control unit 212 may be electrically coupled to the data lines 202, the source tier 204, the conductive contacts 206, the first select gates 208, and the second select gates 210, for example. In some embodiments, the control unit 212 includes CMOS (complementary metal-oxide-semiconductor) circuitry. In such embodiments, the control unit 212 may be characterized as having a “CMOS under Array” (“CuA”) configuration, wherein the CMOS circuitry of a logic region is at least partially (e.g., substantially) positioned within horizontal areas of memory array regions of a microelectronic device including the microelectronic device structures 100, 100′. The conductive fill material 162 (FIGS. 1G and 2B) of the conductive contacts 164 (FIGS. 1G and 2B) and conductive material (e.g., the conductive fill material 162, the conductive material 168 (FIG. 2D)) of the strapping structures 166 (FIGS. 1G and 2B) may be coupled (e.g., electrically connected) to logic circuitry of the control unit 212 underlying the source tier 204, without additional conductive tiers 205 below steps of the staircase structure 220 being coupled to the logic circuitry of the control unit 212. Thus, the strapping structures 166 are coupled to conductive features (e.g., the logic circuitry of the control unit 212) within the source tier 204 through the conductive contacts 164.

Source structures 218 (e.g., corresponding to the source structures 118 (FIG. 1B)) of the source tier 204 may be electrically isolated from other portions thereof (e.g., other portions employed as conductive routing structures 217 (e.g., corresponding to the conductive routing structures 117 (FIG. 1B))). The conductive routing structures 217 may electrically couple components (e.g., the conductive contacts 206, the source structures 218) to circuitry of the control unit 212.

The first select gates 208 may extend horizontally in a first direction (e.g., the Y-direction) and may be coupled to respective first groups of vertically extending strings 207 of memory cells 203 at a first end (e.g., an upper end) of the vertically extending strings 207. The second select gate 210 may be formed in a substantially planar configuration and may be coupled to the vertically extending strings 207 at a second, opposite end (e.g., a lower end) of the vertically extending strings 207 of memory cells 203.

The data lines 202 (e.g., bit lines) may extend horizontally in a second direction (e.g., in the X-direction) that is at an angle (e.g., perpendicular) to the first direction in which the first select gates 208 extend. The data lines 202 may be coupled to respective second groups of the vertically extending strings 207 at the first end (e.g., the upper end) of the vertically extending strings 207. A first group of vertically extending strings 207 coupled to a respective first select gate 208 may share a particular vertically extending string 207 with a second group of vertically extending strings 207 coupled to a respective data line 202. Thus, a particular vertically extending string 207 may be selected at an intersection of a particular first select gate 208 and a particular data line 202. Accordingly, the first select gates 208 may be used for selecting memory cells 203 of the vertically extending strings 207 of memory cells 203.

The conductive tiers 205 (e.g., word line plates, such as the conductive structures 152 (FIGS. 1G and 2B)) may extend in respective horizontal planes. The conductive tiers 205 may be stacked vertically, such that each conductive tier 205 is coupled to all of the vertically extending strings 207 of memory cells 203, and the vertically extending strings 207 of the memory cells 203 extend vertically through the stack of conductive tiers 205. The conductive tiers 205 may be coupled to or may form control gates of the memory cells 203 to which the conductive tiers 205 are coupled. Each conductive tier 205 may be coupled to one memory cell 203 of a particular vertically extending string 207 of memory cells 203.

The first select gates 208 and the second select gates 210 may operate to select a particular vertically extending string 207 of the memory cells 203 between a particular data line 202 and the source tier 204. Thus, a particular memory cell 203 may be selected and electrically coupled to a data line 202 by operation of (e.g., by selecting) the appropriate first select gate 208, second select gate 210, and conductive tier 205 that are coupled to the particular memory cell 203.

The staircase structure 220 may be configured to provide electrical connection directly between the conductive contacts 206 and the conductive tiers 205. Thus, a particular conductive tier 205 may be selected via a conductive contact 206 in electrical communication therewith. The data lines 202 may be electrically coupled to the vertically extending strings 207 through conductive contact structures 234.

Thus, in accordance with embodiments of the disclosure, a method of forming a microelectronic device comprises forming a preliminary stack structure over a source structure. The preliminary stack structure comprises a vertically alternating sequence of insulative material and sacrificial material arranged in preliminary tiers. The method comprises forming a staircase structure having steps comprising edges of at least some of the preliminary tiers of the preliminary stack structure, forming implant regions within exposed portions of the sacrificial material at the steps of the staircase structure, forming openings extending through the preliminary stack structure to the source structure and within a horizontal area of the staircase structure, replacing portions of the sacrificial material with conductive structures, forming strapping structures comprising conductive material, at locations vacated by the implant regions, laterally adjacent to the conductive structures at the steps of the staircase structure, and forming conductive contacts comprising the conductive material within the openings.

Furthermore, in accordance with additional embodiments of the disclosure, a method of forming a microelectronic device comprises forming a stack structure over a source tier including one or more conductive structures. The stack structure comprises tiers each including insulative material and additional insulative material vertically neighboring the insulative material. The method comprises forming a staircase structure within the stack structure. The staircase structure has steps comprising lateral edges of the tiers of the stack structure. The method comprises forming sacrificial material comprising one or more of boron and carbon within exposed portions of uppermost additional insulative material at the steps, forming openings extending through the stack structure and within a horizontal area of the staircase structure. The openings extend through the sacrificial material. The method comprises removing the additional insulative material to form cell openings, removing the sacrificial material to form lateral openings in communication with the openings, forming conductive material within the cell openings and the lateral openings, and forming conductive contacts within the openings. The conductive material is coupled to the one or more conductive structures of the source tier through the conductive contacts.

In accordance with further embodiments of the disclosure a microelectronic device comprises a stack structure overlying a source tier. The stack structure comprises a vertically alternating sequence of conductive structures and insulative structures arranged in tiers. The microelectronic device comprises a staircase structure within the stack structure and having steps comprising lateral edges of the tiers, conductive contacts within a horizontal area of the staircase structure and vertically extending through the stack structure to the source tier, and strapping structures within horizontal areas of the steps of the staircase structure and individually laterally intervening directly between one of the conductive contacts and the conductive structure of one of the tiers of the stack structure. The strapping structures are coupled to conductive features within the source tier through the conductive contacts.

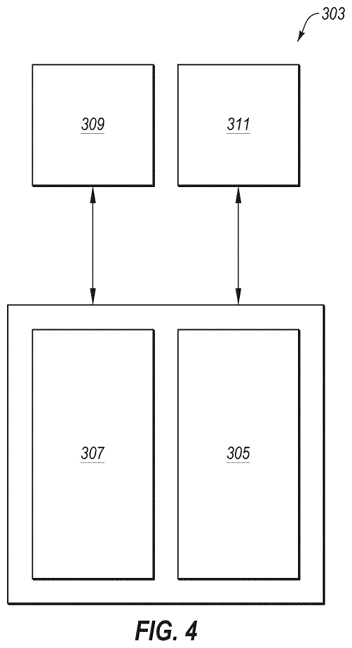

Microelectronic devices (e.g., the microelectronic device 201) including microelectronic device structures (e.g., the microelectronic device structures 100, 100′, 200) of the disclosure may be included in embodiments of electronic systems of the disclosure. For example, FIG. 4 is a schematic block diagram of an electronic system 303, in accordance with embodiments of the disclosure. The electronic system 303 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 303 includes at least one memory device 305. The memory device 305 may include, for example, an embodiment of a microelectronic device structure previously described herein (e.g., the microelectronic device structures 100, 100′, 200 previously described with reference to FIGS. 1A through 2D and FIG. 3) or a microelectronic device (e.g., the microelectronic device 201) previously described with reference to FIG. 3.

The electronic system 303 may further include at least one electronic signal processor device 307 (often referred to as a “microprocessor”). The electronic signal processor device 307 may, optionally, include an embodiment of one or more of a microelectronic device and a microelectronic device structure previously described herein. The electronic system 303 may further include one or more input devices 309 for inputting information into the electronic system 303 by a user, such as, for example, a mouse or other pointing device, a keyboard, a touchpad, a button, or a control panel. The electronic system 303 may further include one or more output devices 311 for outputting information (e.g., visual or audio output) to a user such as, for example, a monitor, a display, a printer, an audio output jack, a speaker, etc. In some embodiments, the input device 309 and the output device 311 may comprise a single touchscreen device that can be used both to input information to the electronic system 303 and to output visual information to a user. The input device 309 and the output device 311 may communicate electrically with one or more of the memory device 305 and the electronic signal processor device 307.

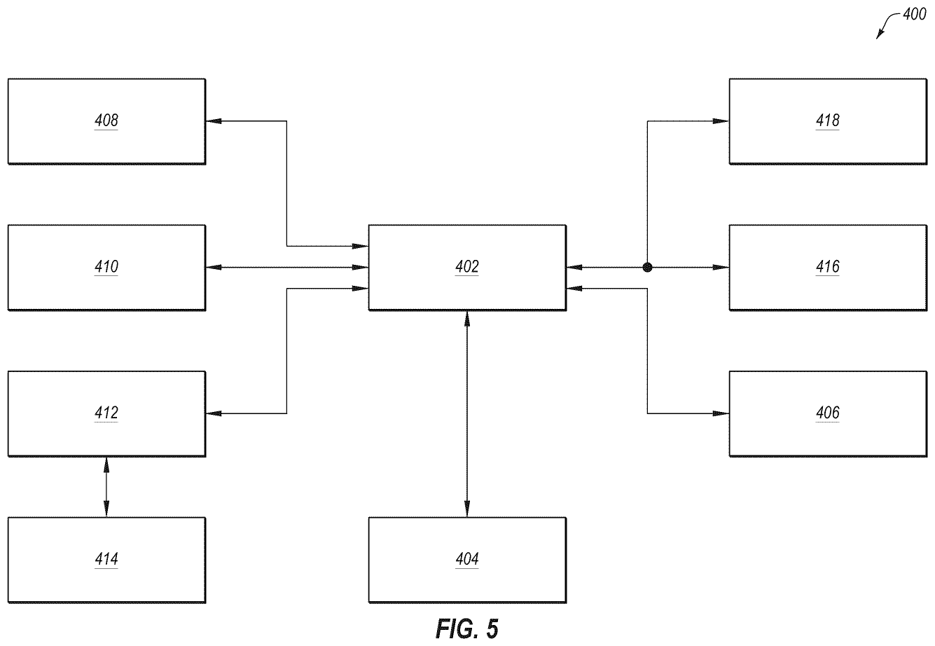

With reference to FIG. 5, depicted is a processor-based system 400. The processor-based system 400 may include one or more of a microelectronic device and a microelectronic device structure previously described herein and manufactured in accordance with embodiments of the disclosure. The processor-based system 400 may be any of a variety of types such as a computer, pager, cellular phone, personal organizer, control circuit, or other electronic device. The processor-based system 400 may include one or more processors 402, such as a microprocessor, to control the processing of system functions and requests in the processor-based system 400. The processor 402 and other subcomponents of the processor-based system 400 may include one or more of a microelectronic device and a microelectronic device structure previously described herein and manufactured in accordance with embodiments of the present disclosure.

The processor-based system 400 may include a power supply 404 in operable communication with the processor 402. For example, if the processor-based system 400 is a portable system, the power supply 404 may include one or more of a fuel cell, a power scavenging device, permanent batteries, replaceable batteries, and rechargeable batteries. The power supply 404 may also include an AC adapter; therefore, the processor-based system 400 may be plugged into a wall outlet, for example. The power supply 404 may also include a DC adapter, such that the processor-based system 400 may be plugged into a vehicle cigarette lighter or a vehicle power port, for example.

Various other devices may be coupled to the processor 402 depending on the functions that the processor-based system 400 performs. For example, a user interface 406 may be coupled to the processor 402. The user interface 406 may include input devices such as buttons, switches, a keyboard, a light pen, a mouse, a digitizer and stylus, a touch screen, a voice recognition system, a microphone, or a combination thereof. A display 408 may also be coupled to the processor 402. The display 408 may include an LCD display, an SED display, a CRT display, a DLP display, a plasma display, an OLED display, an LED display, a three-dimensional projection, an audio display, or a combination thereof. Furthermore, an RF sub-system/baseband processor 410 may also be coupled to the processor 402. The RF sub-system/baseband processor 410 may include an antenna that is coupled to an RF receiver and to an RF transmitter (not shown). A communication port 412, or more than one communication port 412, may also be coupled to the processor 402. The communication port 412 may be adapted to be coupled to one or more peripheral devices 414, such as a modem, a printer, a computer, a scanner, or a camera, or to a network, such as a local area network, remote area network, intranet, or the Internet, for example.

The processor 402 may control the processor-based system 400 by implementing software programs stored in the memory. The software programs may include an operating system, database software, drafting software, word processing software, media editing software, or media playing software, for example. The memory is coupled to the processor 402 to store and facilitate execution of various programs. For example, the processor 402 may be coupled to system memory 416, which may include one or more of spin torque transfer magnetic random access memory (STT-MRAM), magnetic random access memory (MRAM), dynamic random access memory (DRAM), static random access memory (SRAM), racetrack memory, and other known memory types. The system memory 416 may include volatile memory, non-volatile memory, or a combination thereof. The system memory 416 is typically large so that it can store dynamically loaded applications and data. In some embodiments, the system memory 416 may include semiconductor devices, such as one or more of a microelectronic devices and a microelectronic device structure previously described herein.

The processor 402 may also be coupled to non-volatile memory 418, which is not to suggest that system memory 416 is necessarily volatile. The non-volatile memory 418 may include one or more of STT-MRAM, MRAM, read-only memory (ROM) such as an EPROM, resistive read-only memory (RROM), and flash memory to be used in conjunction with the system memory 416. The size of the non-volatile memory 418 is typically selected to be just large enough to store any necessary operating system, application programs, and fixed data. Additionally, the non-volatile memory 418 may include a high-capacity memory such as disk drive memory, such as a hybrid-drive including resistive memory or other types of non-volatile solid-state memory, for example. The non-volatile memory 418 may include microelectronic devices, such as one or more of a microelectronic device and a microelectronic device structure previously described herein.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. A method of forming a microelectronic device, the method comprising:
forming a preliminary stack structure over a source structure, the preliminary stack structure comprising a vertically alternating sequence of insulative material and sacrificial material arranged in preliminary tiers;
forming a staircase structure having steps comprising edges of at least some of the preliminary tiers of the preliminary stack structure;
forming implant regions within exposed portions of the sacrificial material at the steps of the staircase structure;
forming openings extending through the preliminary stack structure to the source structure and within a horizontal area of the staircase structure;
replacing portions of the sacrificial material with conductive structures;
forming strapping structures comprising conductive material, at locations vacated by the implant regions, laterally adjacent to the conductive structures at the steps of the staircase structure; and
forming conductive contacts comprising the conductive material within the openings.

2. The method of claim 1, further comprising forming a sacrificial nitride material in the openings, wherein replacing the portions of the sacrificial material with the conductive structures comprises removing the sacrificial nitride material from the openings during removal of the sacrificial material from cell openings between the insulative material of the preliminary stack structure.

3. The method of claim 1, wherein forming the implant regions comprises forming the implant regions within the exposed portions of an uppermost sacrificial material at the steps of the staircase structure, without forming the implant regions within additional sacrificial material vertically underlying the uppermost sacrificial material.

4. The method of claim 1, wherein forming the implant regions comprises implanting nitride material of the sacrificial material at the steps of the staircase structure with boron, carbon, oxygen, gallium, or a combination thereof.

5. The method of claim 1, wherein replacing the portions of the sacrificial material with the conductive structures comprises removing the sacrificial material of the preliminary stack structure and a boron-doped or a carbon-doped nitride material of the implant regions in a single processing act.

6. The method of claim 1, further comprising:
forming lateral openings in communication with the openings, each of the lateral openings individually at an elevational level of one of the steps,
wherein forming the conductive structures comprises forming High-K dielectric material adjacent to the conductive structures, without forming the High-K dielectric material within the lateral openings.

7. A method of forming a microelectronic device, the method comprising:
forming a stack structure over a source tier including one or more conductive structures, the stack structure comprising tiers each including insulative material and additional insulative material vertically neighboring the insulative material;
forming a staircase structure within the stack structure, the staircase structure having steps comprising lateral edges of the tiers of the stack structure;
forming sacrificial material comprising one or more of boron and carbon within exposed portions of uppermost additional insulative material at the steps;
forming openings extending through the stack structure and within a horizontal area of the staircase structure, the openings extending through the sacrificial material;
removing the additional insulative material to form cell openings;
removing the sacrificial material to form lateral openings in communication with the openings;
forming conductive material within the cell openings and the lateral openings; and
forming conductive contacts within the openings, the conductive material coupled to the one or more conductive structures of the source tier through the conductive contacts.

8. The method of claim 7, further comprising forming one or more of High-K dielectric material and conductive liner material adjacent to the insulative material of the stack structure, the one or more of the High-K dielectric material and the conductive liner material vertically interposed between the conductive material and the insulative material of the stack structure and horizontally interposed between the conductive contacts and the insulative material.

9. The method of claim 7, wherein forming the conductive material within the cell openings and the lateral openings comprises forming additional portions of the conductive material within the openings.

10. The method of claim 7, further comprising:
forming dielectric material over the stack structure to enclose the openings prior to forming the conductive material within the cell openings and the lateral openings; and
forming the conductive material within the openings without fully filling the openings.

11. The method of claim 7, wherein forming the conductive contacts comprises forming additional conductive material directly laterally adjacent to the conductive material within the lateral openings.

12. The method of claim 7, wherein removing the additional insulative material comprises substantially simultaneously removing doped nitride material of the sacrificial material to form the lateral openings during formation of the cell openings.

13. A microelectronic device, comprising:
a stack structure overlying a source tier, the stack structure comprising a vertically alternating sequence of conductive structures and insulative structures arranged in tiers;
a staircase structure within the stack structure and having steps comprising lateral edges of the tiers;
conductive contacts within a horizontal area of the staircase structure and vertically extending through the stack structure to the source tier; and
strapping structures within horizontal areas of the steps of the staircase structure and individually laterally intervening directly between one of the conductive contacts and the conductive structure of one of the tiers of the stack structure, the strapping structures coupled to conductive features within the source tier through the conductive contacts.

14. The microelectronic device of claim 13, further comprising High-K dielectric material adjacent to the insulative structures of the stack structure, the High-K dielectric material substantially surrounding the strapping structures on three consecutive sides.

15. The microelectronic device of claim 13, wherein:
the strapping structures substantially laterally surround the conductive contacts; and
conductive material of the conductive structures of the tiers of the stack structure substantially laterally surrounds each of the strapping structures.

16. The microelectronic device of claim 13, wherein the conductive contacts comprise portions of conductive material of the conductive structures of the stack structure at least partially laterally surrounding additional conductive material.

17. The microelectronic device of claim 13, wherein the conductive contacts vertically extend through the stack structure from an upper surface of the stack structure to additional conductive structures within the source tier, each of the conductive contacts exhibiting substantially the same vertical height.

18. The microelectronic device of claim 13, wherein the strapping structures comprise conductive pad structures at the steps of the staircase structure, the conductive pad structures comprising first portions laterally adjacent to the conductive structures and second portions having relatively larger thickness laterally adjacent to the first portions and substantially laterally surrounding the conductive contacts.

19. The microelectronic device of claim 13, wherein the strapping structures are individually vertically adjacent to the insulative structure of the one of the tiers of the stack structure.

20. The microelectronic device of claim 13, wherein:
a material composition of the strapping structures is substantially the same as a material composition of the conductive structures of the stack structure; and
a material composition of the conductive contacts differs from the material composition of each of the strapping structures and the conductive structures.
